(19) United States
(12) Patent Application Publication
(10) Pub. No.: US 2026/0136669 A1
(43) Pub. Date: May 14, 2026

(54) ARRAY SUBSTRATE AND DISPLAY DEVICE

(71) Applicants: WUHAN BOE OPTOELECTRONICS TECHNOLOGY CO., LTD., Wuhan (CN); BOE TECHNOLOGY GROUP CO., LTD., Beijing (CN)

(72) Inventors: Yan ZHOU, Beijing (CN); Ning ZHU, Beijing (CN); Chao WANG, Beijing (CN); Yun LI, Beijing (CN); Xiaoxiao CHEN, Beijing (CN); Yi ZHANG, Beijing (CN)

(73) Assignees: WUHAN BOE OPTOELECTRONICS TECHNOLOGY CO., LTD., Wuhan (CN); BOE TECHNOLOGY GROUP CO., LTD., Beijing (CN)

(21) Appl. No.: 18/993,244

(22) PCT Filed: Apr. 28, 2024
(86) PCT No.: PCT/CN2024/090260

§ 371 Date: Jan. 10, 2025

(30) Foreign Application Priority Data
May 29, 2023 (CN) 202310620215.2

(51) Int. Cl. H10D 86/40

(52) U.S. Cl. CPC H10D 86/441

(57) ABSTRACT

An array substrate and a display device are provided. The array substrate includes a base substrate, and a first electrode layer, a plurality of first signal lines, and a plurality of second signal lines on the base substrate, the first signal lines are arranged in a first direction, the second signal lines are arranged in a second direction; the first electrode layer includes a plurality of first electrodes arranged in an array in the first direction and the second direction, a connection portion is provided between adjacent two first electrodes on two sides of a same first signal line, and the connection portion is configured to connect the two first electrodes; and the connection portion is closer to the second signal line relative to a straight line that passes through a central region of the first electrode and extends in the first direction.

The present application claims the priority to Chinese Patent Application No. 202310620215.2, filed on May 29, 2023, the entire disclosure of which is incorporated herein by reference as portion of the present application.

### TECHNICAL FIELD

Embodiments of the present disclosure relate to an array substrate and a display device.

### BACKGROUND

With the development of display technology, there is an increasing requirement for sizes and display effect of display devices. Large-sized display devices adopting the advanced super dimension switching (ADS) display mode have characteristics such as high aperture ratio, high resolution, high transmittance, and the like, making them widely used.

### SUMMARY

Embodiments of the present disclosure provide an array substrate and a display device.

The array substrate provided by the embodiments of the present disclosure includes a base substrate, and a first electrode layer, a plurality of first signal lines, and a plurality of second signal lines on the base substrate, the plurality of first signal lines are arranged in a first direction, the plurality of second signal lines are arranged in a second direction, and the first direction intersects with the second direction; the first electrode layer comprises a plurality of first electrodes arranged in an array in the first direction and the second direction, a connection portion is provided between adjacent two first electrodes on two sides of a same first signal line, and the connection portion is configured to connect the two first electrodes; and the connection portion is closer to the second signal line relative to a straight line that passes through a central region of the first electrode and extends in the first direction.

For example, according to the embodiments of the present disclosure, in the second direction, a distance between the first electrode and the second signal line is not greater than a distance between the connection portion and the second signal line.

For example, according to the embodiments of the present disclosure, the array substrate further comprises a plurality of sub-pixels, the plurality of sub-pixels comprise at least a first color sub-pixel and a second color sub-pixel, and both the first color sub-pixel and the second color sub-pixel comprise multiple domains; and a protrusion portion is provided in a light-emitting region of one of the first color sub-pixel and the second color sub-pixel, and the protrusion portion is between two adjacent domains among the multiple domains.

For example, according to the embodiments of the present disclosure, in the first color sub-pixel and the second color sub-pixel, the first electrode comprises a plurality of strip electrodes, and extension directions of strip electrodes in two adjacent domains intersect with each other; and in a direction perpendicular to the base substrate, the protrusion portion overlaps with the strip electrode in at least one of the two adjacent domains, or the protrusion portion does not overlap with the strip electrode.

For example, according to the embodiments of the present disclosure, the protrusion portion is provided in a same layer as one of the first signal line and the second signal line.

For example, according to the embodiments of the present disclosure, one of the first color sub-pixel and the second color sub-pixel is a red sub-pixel, and the other is a blue sub-pixel.

For example, according to the embodiments of the present disclosure, in a direction perpendicular to the base substrate, an edge of the protrusion portion does not overlap with a light-emitting region of an adjacent sub-pixel, and a size of the protrusion portion in an arrangement direction of the two adjacent domains ranges from 1.5 microns to 6 microns.

For example, according to the embodiments of the present disclosure, a width of the connection portion is greater than a width of the strip electrode, and the width of the connection portion is not greater than 10 microns.

For example, according to the embodiments of the present disclosure, the array substrate further comprises a second electrode layer stacked with the first electrode layer, the second electrode layer comprises a plurality of second electrodes, and each sub-pixel comprises one second electrode.

For example, according to the embodiments of the present disclosure, a total number of the connection portion provided between the two first electrodes in the first direction is at least one.

For example, according to the embodiments of the present disclosure, the connection portion and the two first electrodes are configured as an integrated structure.

For example, according to the embodiments of the present disclosure, two sub-pixels arranged in the first direction are provided between two adjacent first signal lines, and two second signal lines are provided between two adjacent sub-pixels arranged in the second direction; the first signal line is a data line, and the second signal line is a gate line.

For example, according to the embodiments of the present disclosure, first electrodes of adjacent sub-pixels, which are between two adjacent first signal lines and arranged in the first direction, are configured as an integrated structure; and a spacing is provided between the first electrodes of adjacent sub-pixels on two sides of the first signal line and arranged in the first direction, and the first signal line is provided in the spacing.

For example, according to the embodiments of the present disclosure, the array substrate comprises a display region and a non-display region on at least one side of the display region. A plurality of sub-pixels, the plurality of first signal lines, and the plurality of second signal lines are all in the display region; the array substrate further comprises a plurality of signal transmission lines in the non-display region and provided in a same layer as the second signal lines, and comprises connection lines electrically connected to the signal transmission lines; the connection lines extend in the first direction, the signal transmission lines extend in the second direction, and the connection lines are provided in a same layer as the first signal lines; and in a direction perpendicular to the base substrate, at least one signal transmission line overlaps with the connection lines, and an edge of an overlapping portion of the signal transmission line with the connection lines comprises a notch, so that a size of the overlapping portion in an extension direction of the connection wires is smaller than a size of at least part, except for the overlapping portion, of the signal transmission line in the extension direction of the connection wires.

Another embodiment of the present disclosure provides a display device, which comprises the above array substrate and an opposite substrate provided opposite to the array substrate, the opposite substrate comprises a light-shielding layer, and the light-shielding layer comprises a plurality of openings to define light-emitting regions of sub-pixels; an orthographic projection of the first signal line on the base substrate comprises a first orthographic projection, an orthographic projection of the connection portion on the base substrate comprises a second orthographic projection, and the second orthographic projection is within an orthographic projection of the light-shielding layer on the base substrate; an orthographic projection of the opening on the base substrate comprises a third orthographic projection, and a distance between edges, close to each other, of the first orthographic projection and the third orthographic projection is a first distance; and the first orthographic projection comprises an overlapping edge overlapping with the second orthographic projection, a distance between the overlapping edge and a closest edge of the third orthographic projection to the overlapping edge is a second distance, and the second distance is greater than the first distance.

For example, according to the embodiments of the present disclosure, the first signal line extends in the second direction, the opening comprises an opening edge extending in the second direction and closest to the first signal line, and the connection portion is between the opening edge and a second signal line that is closest to the opening edge.

For example, according to the embodiments of the present disclosure, a straight line passing through the connection portion and extending in the first direction does not pass through the opening edge.

Another embodiment of the present disclosure provides an array substrate, which comprises a base substrate and a plurality of sub-pixels, a plurality of data lines, a plurality of gate lines and a plurality of common electrode lines on the base substrate. The base substrate comprises a display region and a first non-display region on at least one side of the display region; the plurality of sub-pixels are in the display region of the base substrate, each of the sub-pixels comprises a first electrode and a second electrode stacked with each other; the plurality of data lines are in the display region of the base substrate and configured to be electrically connected to second electrodes, the plurality of data lines are arranged in a first direction; the plurality of gate lines are in the display region of the base substrate and arranged in a second direction, the second direction intersects with the first direction; the plurality of common electrode lines are in the display region of the base substrate and electrically connected to first electrodes, the plurality of common electrode lines and the plurality of data lines are alternately arranged in the first direction; the array substrate further comprises a common signal transmission line in the first non-display region, and the common signal transmission line comprises a first common signal transmission line and a second common signal transmission line; the second common signal transmission line is provided on a side of the first common signal transmission line away from the display region, and the common signal transmission line extends in the first direction; the first common signal transmission line is electrically connected to a part of the plurality of common electrode lines, and the second common signal transmission line is electrically connected to another part of the plurality of common electrode lines; and the first non-display region further comprises a pad region configured to be electrically connected to a circuit board.

For example, according to the embodiments of the present disclosure, the array substrate further comprises a second non-display region, the first non-display region, the display region, and the second non-display region are arranged sequentially in the second direction; and the common signal transmission line further comprises a third common signal transmission line and a fourth common signal transmission line both in the second non-display region, the fourth common signal transmission line is on a side of the third common signal transmission line away from the display region, the third common signal transmission line is electrically connected to the second common signal transmission line, and the fourth common signal transmission line is electrically connected to the first common signal transmission line.

For example, according to the embodiments of the present disclosure, two gate lines are provided between two adjacent sub-pixels arranged in the second direction, two sub-pixels arranged in the first direction are provided between two adjacent data lines, and first electrodes of the two sub-pixels are configured as an integrated structure.

For example, according to the embodiments of the present disclosure, the array substrate further comprises a transfer portion, at least one common electrode line is electrically connected to the common signal transmission line through the transfer portion; the at least one common electrode line comprises a first conductive layer and a second conductive layer stacked with each other, the first conductive layer is provided in a same layer as the data lines, the second conductive layer is provided in a same layer as the first electrode, and at least a portion of the common signal transmission line is provided in a same layer as the gate lines; and the transfer portion comprises a first transfer layer and a second transfer layer stacked with each other, the first transfer layer is provided in a same layer as the first conductive layer, and the second transfer layer is provided in a same layer as the second conductive layer.

For example, according to the embodiments of the present disclosure, the array substrate further comprises a third non-display region and a fourth non-display region, the third non-display region, the display region, and the fourth non-display region are arranged sequentially in the first direction; and the third non-display region is provided with a first connection line to connect the second common signal transmission line and the third common signal transmission line, the fourth non-display region is provided with a second connection line to connect the first common signal transmission line and the fourth common signal transmission line, and at least a portion of the first connection line, at least a portion of the second connection line, and at least a portion of the common signal transmission line are provided in a same layer.

For example, according to the embodiments of the present disclosure, the third non-display region is provided with a fifth common signal transmission line, a first gate driving circuit, and a first common signal feedback line; both the fifth common signal transmission line and the first common signal feedback line are electrically connected to the third common signal transmission line, and the first gate driving circuit is electrically connected to the plurality of gate lines; and the fifth common signal transmission line and the first common signal feedback line are both on a side of the first gate driving circuit away from the display region, and the first connection line is between the first gate driving circuit and the display region.

For example, according to the embodiments of the present disclosure, the fourth non-display region is provided with a sixth common signal transmission line, a second gate driving circuit, and a second common signal feedback line; both the sixth common signal transmission line and the second common signal feedback line are electrically connected to the fourth common signal transmission line, and the second gate driving circuit is electrically connected to the plurality of gate lines; and the sixth common signal transmission line and the second common signal feedback line are both on a side of the second gate driving circuit away from the display region, and the second connection line is between the second gate driving circuit and the display region.

For example, according to the embodiments of the present disclosure, first electrodes of two columns of sub-pixels between adjacent data lines are electrically connected to a same common electrode line; and first electrodes of two columns of sub-pixels that are on two sides of a same data line and closest to the same data line are spaced apart from each other, and are electrically connected to the first common signal transmission line and the second common signal transmission line, respectively.

For example, according to the embodiments of the present disclosure, the first common signal transmission line and the second common signal transmission line are configured to transmit different electrical signals.

Another embodiment of the present disclosure provides a display device, which comprises any one of the above array substrates.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic diagram of a partial planar structure of a display device;

FIG. 2 is a schematic diagram of a common electrode layer in the display device shown in FIG. 1;

FIG. 3 is a schematic diagram of a black matrix in the display device shown in FIG. 1;

FIG. 4 is a schematic diagram of a partial planar structure of an array substrate provided by the embodiments of the present disclosure;

FIG. 5 is a schematic diagram of a second electrode layer in the array substrate shown in FIG. 4;

FIG. 6 is a schematic diagram of a layer where a second signal line is located in the array substrate shown in FIG. 4;

FIG. 7 is a schematic diagram of an active layer in the array substrate shown in FIG. 4;

FIG. 8 is a schematic diagram of a layer where a first signal line is located in the array substrate shown in FIG. 4;

FIG. 9 is a schematic diagram of vias in the array substrate shown in FIG. 4;

FIG. 10A is a schematic diagram of a layer where a first electrode layer is located in the array substrate shown in FIG. 4;

FIG. 10B is a schematic diagram of a layer where a first electrode layer is located, provided by another example according to the embodiments of the present disclosure;

FIG. 11 is a partial structural diagram of a display device including the above-mentioned array substrate;

FIG. 12 is a diagram showing a planar relationship between a black matrix and an array substrate in the display device shown in FIG. 11;

FIG. 13 is a plan view of the black matrix in the display device shown in FIG. 11;

FIG. 14 is an enlarged view of a partial structure in FIG. 12;

FIG. 15 is a schematic diagram of a partial planar structure of an array substrate provided by another example of the embodiments of the present disclosure;

FIG. 16 is a partial enlarged view of the array substrate shown in FIG. 15;

FIG. 17 is a schematic diagram of a layer where a first signal line is located in the array substrate shown in FIG. 15;

FIG. 18 is a schematic diagram of a planar structure of an array substrate provided by the embodiments of the present disclosure;

FIG. 19 is a schematic diagram of signal transmission lines and connection lines in an array substrate;

FIG. 20 is a schematic diagram of signal transmission lines, connection lines, and connection structures provided by the embodiments of the present disclosure;

FIG. 21 is a schematic diagram of the signal transmission lines shown in FIG. 20;

FIG. 22 is a schematic diagram of the connection lines shown in FIG. 20;

FIG. 23 and FIG. 24 are schematic diagrams of vias and connection structures shown in FIG. 20;

FIG. 25 is a schematic diagram of a partial planar structure of an array substrate;

FIG. 26 to FIG. 28 are schematic diagrams of different layers in the array substrate shown in FIG. 25;

FIG. 29 is a schematic diagram of a planar structure of an array substrate provided by the embodiments of the present disclosure;

FIG. 30 is a partial enlarged view of a display region and a second non-display region in the array substrate shown in FIG. 29;

FIG. 31 is a schematic diagram of a layer where a second electrode of a sub-pixel is located in the array substrate shown in FIG. 30;

FIG. 32 is a schematic diagram of a layer where a gate line is located in the array substrate shown in FIG. 30;

FIG. 33 is a schematic diagram of a layer where a data line is located in the array substrate shown in FIG. 30;

FIG. 34 is a schematic diagram of vias in the array substrate shown in FIG. 30; and

FIG. 35 is a schematic diagram of a layer where a first electrode of a sub-pixel is located in the array substrate shown in FIG. 30.

### DETAILED DESCRIPTION

In order to make objectives, technical details, and advantages of the embodiments of the present disclosure clearer, the technical solutions of the embodiments of the present disclosure will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. Features such as “parallel”, “vertical/perpendicular” and “identical/same” used in the embodiments of the present disclosure include features such as “parallel”, “vertical/perpendicular” and “identical/same” in the strict sense, as well as “approximately parallel”, “approximately vertical/perpendicular” and “approximately identical/same” and other situations that contain certain errors. Considering the measurement and errors associated with the measurement of a specific value (such as limitations of the measurement system), it represents the acceptable deviation range for a specific value determined by those skilled in the art. For example, the above-mentioned “substantially” can mean that the deviation is within one or more standard deviations, or within 10% or 5% of the value. When the number of one component or element is not specified in the following of the embodiments of the present disclosure, it means that the component or element can be one or more, or can be understood as at least one. “At least one” means one or more, and “a plurality of” means at least two. In the present disclosure, “provided in a/the same layer” refers to two (or more than two) structures, which are provided in a/the same layer, are formed by the same deposition process and patterned by the same patterning process, and materials of the two structures are the same or different.

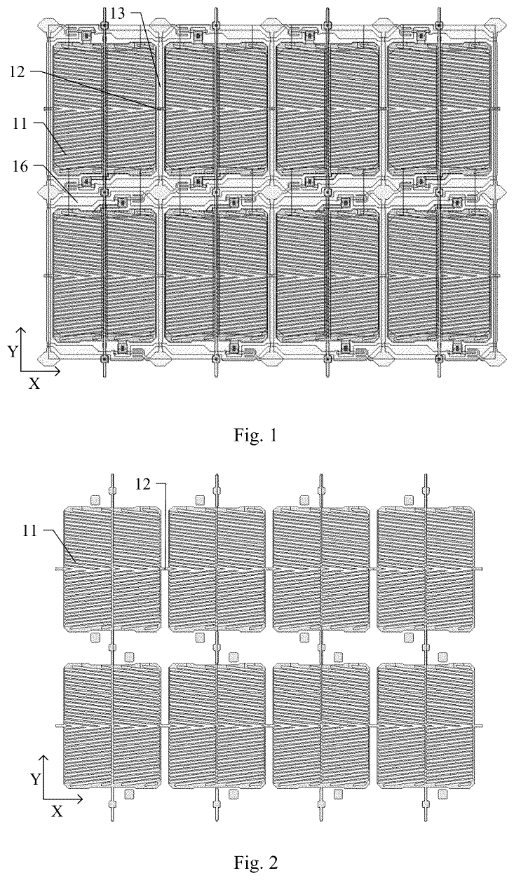

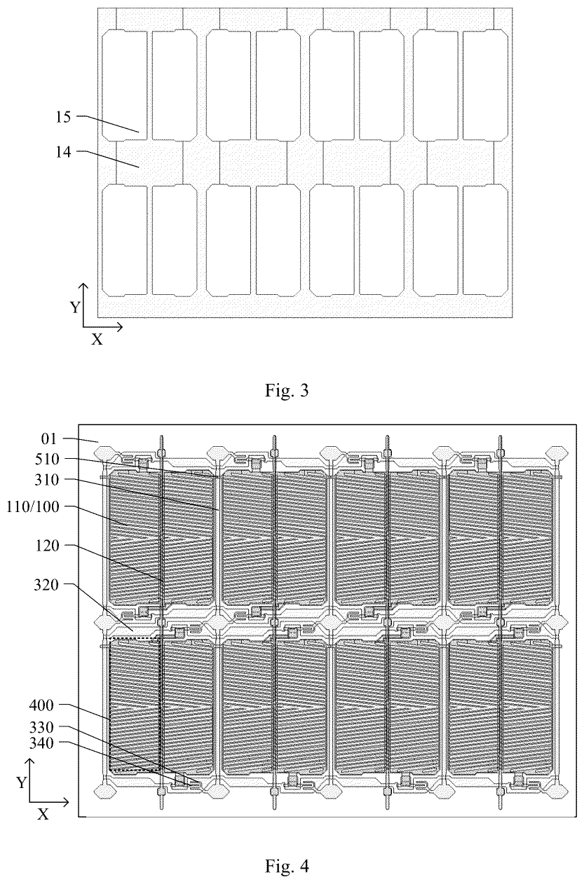

FIG. 1 is a schematic diagram of a partial planar structure of a display device. FIG. 2 is a schematic diagram of a common electrode layer in the display device shown in FIG. 1. FIG. 3 is a schematic diagram of a black matrix in the display device shown in FIG. 1.

As shown in FIG. 1 to FIG. 3, the display device may adopt a dual-gate structure, two columns of sub-pixels are arranged between two adjacent data lines 13 arranged in the X direction, and two gate lines 16 are arranged between two adjacent rows of sub-pixels arranged in the Y direction. The adoption of dual-gate technology helps reduce the number of data lines, thereby reducing the number of source driver chips and reducing costs. The display device further includes a black matrix 14, which includes a plurality of openings 15 to define light-emitting regions of the sub-pixels.

In a display panel of a large-sized display device with a dual-gate design, a top-layer transparent conductive layer, such as indium tin oxide (ITO), is commonly used as a common electrode in the pixel structure, as shown by a common electrode 11 in FIG. 2. The common electrodes 11 located on two sides of the data line 13 are electrically connected to each other through a connection portion 12, for example, the connection portion 12 is in a region between the centers of adjacent sub-pixels.

During the research, the inventor(s) of the present disclosure found that large-sized display panels adopting dual-gate technology are prone to issues such as high load. The issues of high load can be addressed by increasing the distance between the pixel electrode and the data line, or by increasing the distance between the common electrode and the data line. However, the common electrodes on two sides of the data line are electrically connected to each other through a connection portion; because the distance between the pixel electrode or common electrode and the data line increases, the electric field acting on liquid crystals near the connection portion becomes weaker; the width of the black matrix, used to shield the data line, is limited by the aperture ratio, the width at the location of the connection portion cannot be larger; in this case, if there is a misalignment between the data line and the black matrix, it significantly increases the risk of light leakage at the location of the connection portion.

The present disclosure provides an array substrate and a display device.

The embodiments of the present disclosure provide an array substrate, which includes a base substrate, and includes a first electrode layer, a plurality of first signal lines, and a plurality of second signal lines on the base substrate. The plurality of first signal lines are arranged in a first direction, the plurality of second signal lines are arranged in a second direction, and the first direction intersects with the second direction. The first electrode layer includes a plurality of first electrodes arranged in an array in the first direction and the second direction, a connection portion is provided between adjacent two first electrodes on two sides of the same first signal line, and the connection portion is configured to connect the two first electrodes; and the connection portion is closer to the second signal line relative to a straight line that passes through a central region of the first electrode and extends in the first direction. The array substrate provided by the present disclosure provides the connection portion closer to the second signal line, thereby reducing the load of the display device without affecting the aperture ratio, and reducing the risk of light leakage.

Another array substrate provided by the embodiments of the present disclosure includes a base substrate and includes a plurality of sub-pixels, a plurality of data lines and a plurality of common electrode lines on the base substrate. The base substrate includes a display region and a first non-display region on at least one side of the display region; the plurality of sub-pixels are in the display region, and each sub-pixel includes a first electrode and a second electrode stacked with each other; the plurality of data lines are in the display region and configured to be electrically connected to second electrodes, and the plurality of data lines are arranged in a first direction; the plurality of gate lines are in the display region and arranged in a second direction, and the second direction intersects with the first direction; the plurality of common electrode lines are in the display region and electrically connected to first electrodes, and the plurality of common electrode lines and the plurality of data lines are alternately arranged in the first direction. The array substrate further includes a common signal transmission line in the first non-display region, and the common signal transmission line includes a first common signal transmission line and a second common signal transmission line; the second common signal transmission line is provided on a side of the first common signal transmission line away from the display region, and the common signal transmission line extends in the first direction; the first common signal transmission line is electrically connected to a part of the plurality of common electrode lines, and the second common signal transmission line is electrically connected to another part of the common electrode lines; and the first non-display region further includes a pad region configured to be electrically connected to a circuit board. By providing two common signal transmission lines (including the first common signal transmission line and the second common signal transmission line) that transmit different electrical signals, the array substrate provided by the present disclosure is beneficial to reducing or eliminating issues such as non-uniform display brightness and linear mura.

The array substrate and display device provided by the embodiments of the present disclosure are described below in conjunction with the drawings.

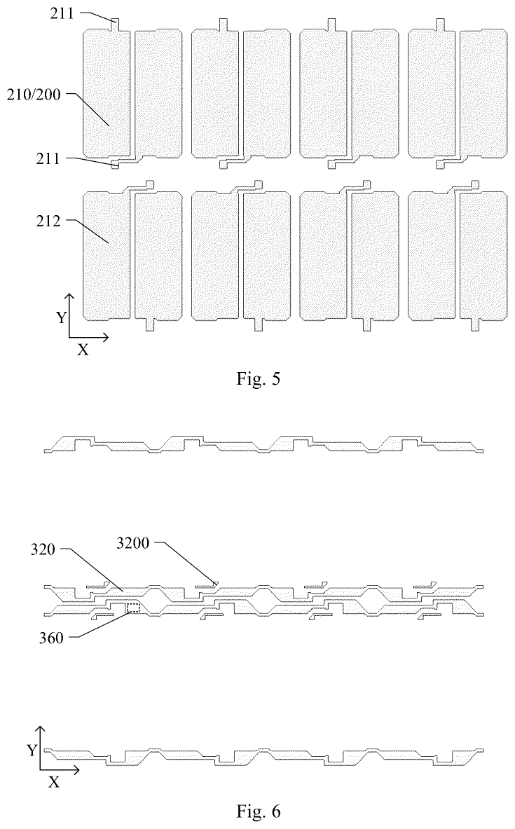

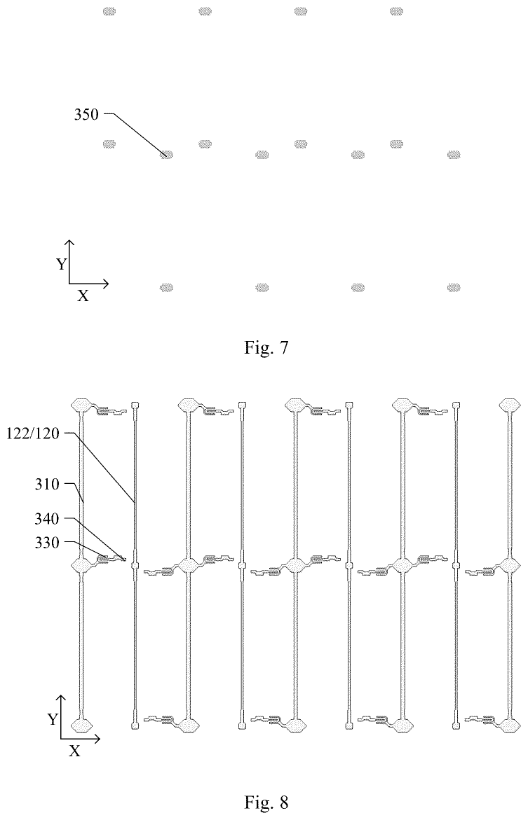

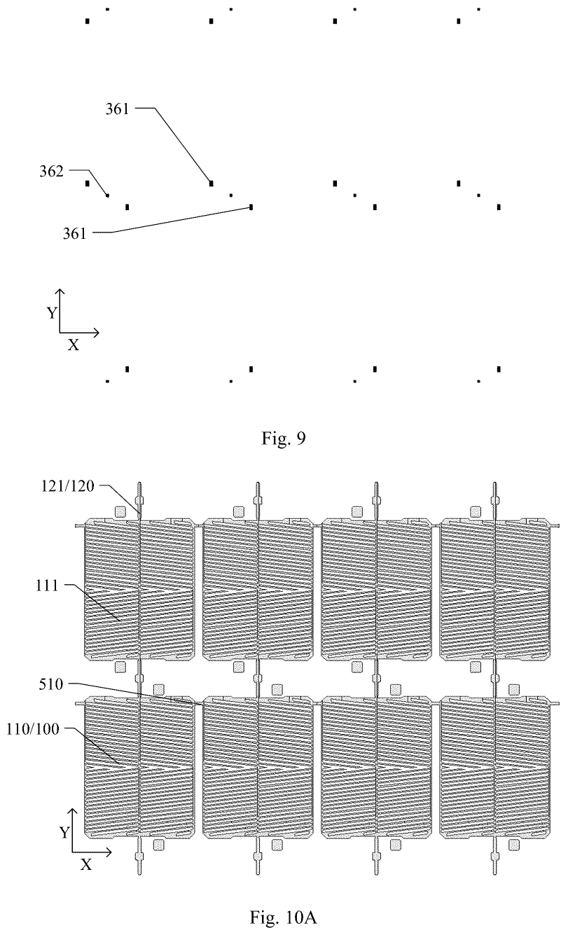

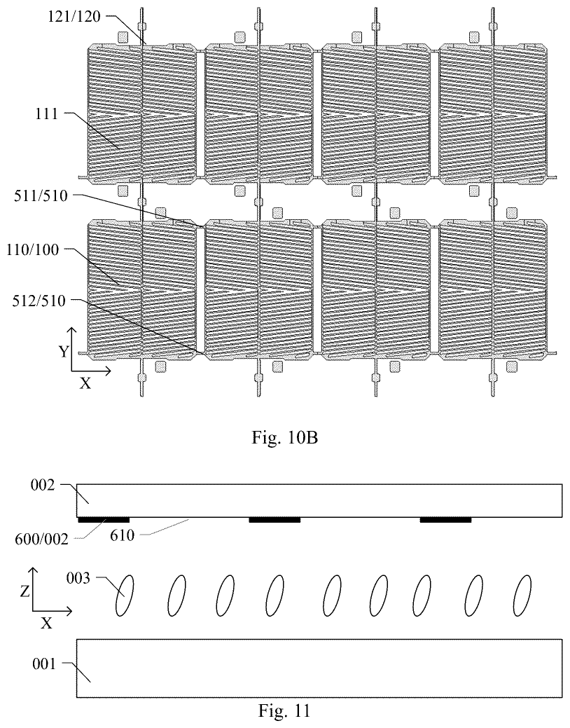

FIG. 4 is a schematic diagram of a partial planar structure of an array substrate provided by the embodiments of the present disclosure; FIG. 5 is a schematic diagram of a second electrode layer in the array substrate shown in FIG. 4; FIG. 6 is a schematic diagram of a layer where a second signal line is located in the array substrate shown in FIG. 4; FIG. 7 is a schematic diagram of an active layer in the array substrate shown in FIG. 4; FIG. 8 is a schematic diagram of a layer where a first signal line is located in the array substrate shown in FIG. 4; FIG. 9 is a schematic diagram of vias in the array substrate shown in FIG. 4; and FIG. 10A is a schematic diagram of a layer where a first electrode layer is located in the array substrate shown in FIG. 4.

As shown in FIG. 4 to FIG. 10A, the array substrate includes a base substrate 01, and a first electrode layer 100, a plurality of first signal lines 310, and a plurality of second signal lines 320 on the base substrate 01. The plurality of first signal lines 310 are arranged in a first direction, the plurality of second signal lines 320 are arranged in a second direction, and the first direction intersects with the second direction. For example, the first direction may be the X direction shown in figures, and the second direction may be the Y direction shown in figures, but the embodiments are not limited thereto, and the first direction and the second direction can be interchanged. For example, the angle between the first direction and the second direction may be 80 degrees-100 degrees, for example, the first direction is perpendicular to the second direction.

As shown in FIG. 4 and FIG. 10A, the first electrode layer 100 includes a plurality of first electrodes 110 arranged in an array in the first direction and the second direction.

In some examples, as shown in FIG. 4, the array substrate includes a plurality of sub-pixels 400. For example, the plurality of sub-pixels 400 are arranged in an array in the first direction and the second direction.

In some examples, as shown in FIG. 4 and FIG. 5, the array substrate further includes a second electrode layer 200 stacked with the first electrode layer 100. The second electrode layer 200 includes a plurality of second electrodes 210, and each sub-pixel 400 includes one second electrode 210. For example, the second electrode 210 may be served as a pixel electrode. For example, the second electrode 210 may be made of a transparent conductive material, such as indium tin oxide (ITO).

In some examples, as shown in FIG. 4 and FIG. 10A, two sub-pixels 400 arranged in the first direction are provided between two adjacent first signal lines 310, and two second signal lines 320 are provided between two adjacent sub-pixels 400 arranged in the second direction; the first signal line 310 is a data line, and the second signal line 320 is a gate line. The array substrate provided by the present disclosure adopts the dual-gate technology, such as a driving technology that reduces the number of data lines by half and doubles the number of gate lines, that is, reduces the number of source driver integrated circuits (ICs) connected to the data lines by half and doubles the number of gate driver integrated circuits connected to the gate lines, thereby achieving cost reduction.

In some examples, as shown in FIG. 4, FIG. 8, and FIG. 10A, first electrodes 110 of adjacent sub-pixels 400, which are between two adjacent first signal lines 310 and arranged in the first direction, are configured as an integrated structure; and a spacing is provided between the first electrodes 110 of adjacent sub-pixels 400 on two sides of the first signal line 310 and arranged in the first direction, and the first signal line 310 is provided in the spacing.

For example, as shown in FIG. 4, FIG. 8, and FIG. 10A, each sub-pixel 400 includes a transistor, and the transistor includes a first electrode 330, a second electrode 340, an active layer 350, and a gate electrode 360. The gate electrode 360 overlaps with the active layer 350 and can form a part of the second signal line 320. For example, a same first signal line 310 is connected to first electrodes 330 of transistors of two adjacent sub-pixels 400 on the same side of the same first signal line 310 and in the same row; and second electrodes 210 of the above-mentioned two adjacent sub-pixels 400 are connected to the second electrode 340 of the transistor. Optionally, the second electrode of the transistor extends in the first direction and overlaps with the gate line in the direction perpendicular to the base substrate. The gate electrodes 360 of the transistors of the two adjacent sub-pixels 400 are electrically connected to different second signal lines 320, and these different second signal lines 320 are provided on two sides of the above-mentioned two adjacent sub-pixels 400 in the Y direction.

For example, as shown in FIG. 4, FIG. 5, and FIG. 10A, two second electrodes 210 arranged in the first direction are provided between two adjacent first signal lines 310, and one first electrode 110 corresponds to two second electrodes 210. For example, the distance between two second electrodes 210 arranged in the first direction and between two adjacent first signal lines 310 is less than the distance between two adjacent second electrodes 210 provided on two sides of the first signal line 310.

For example, as illustrated in FIG. 5 and FIG. 6, the second electrode 210 and the second signal line 320 may be provided in the same layer. For example, the second electrode 210 and the second signal line 320 may be formed using the same mask. For example, the material of the second electrode 210 is different from the material of the second signal line 320. For example, no insulating layer is provided between the layer where the second electrode 210 is located and the layer where the second signal line 320 is located. For example, the layer where the second signal line 320 is located includes a stacked portion 3200, and the stacked portion 3200 is stacked with a second electrode connection portion 211 of the second electrode 210, without an insulating layer provided therebetween, and the stacked portion 3200 and the second electrode connection portion 211 of the second electrode 210 are in direct contact to achieve electrical connection, which is beneficial to improving the electrical performance of the second electrode.

For example, as shown in FIG. 4, FIG. 5, FIG. 8, and FIG. 9, the shapes of second electrode connection portions 211, electrically connected to the second electrode 340 of the transistor, in the two adjacent second electrodes 210 arranged in the first direction and between two adjacent first signal lines 310 are different; and the second electrode connection portion 211 is electrically connected to the second electrode 240 of the transistor through a via 361 penetrating through the insulating layer between the second electrode 210 and the second electrode 240 of the transistor. For example, the orthographic projection of the second electrode connection portion 211 on the base substrate 01 is within the orthogonal projection of a light-shielding layer (described later), such as a black matrix, on the base substrate 01.

As illustrated in FIG. 4 and FIG. 5, the two adjacent second electrodes 210 arranged in the first direction between two adjacent first signal lines 310 further include two second electrode main portions 212 except the second electrode connection portion 211. These two second electrode main portions 212 are substantially symmetrically distributed relative to a common electrode line 120 (described later), which is beneficial to improving the pixel aperture ratio.

As illustrated in FIG. 4 and FIG. 10A, a connection portion 510 is provided between adjacent two first electrodes 110 on two sides of the same first signal line 310, and the connection portion 510 is configured to connect the two first electrodes 110.

As shown in FIG. 4 and FIG. 10A, optionally, the connection portion 510 is closer to the second signal line 320 relative to a straight line that passes through a central region of the first electrode 110 and extends in the first direction. For example, the “central region” of the first electrode may refer to a region that includes the geometric center of the first electrode. The region may be a circular or square region surrounding the geometric center, etc., and the area of the region should not exceed 10% of the area of the first electrode, such as not exceeding 5%, or not exceeding 2%, and so on.

The array substrate provided by the present disclosure provides the connection portion closer to the second signal line, thereby reducing the load of the display device without affecting the aperture ratio, and reducing the risk of light leakage.

For example, as shown in FIG. 4, a ratio of a distance between the connection portion 510 and a straight line that passes through the central region of the first electrode 110, such as a center of the central region, and extends in the first direction to a size of the first electrode 110 in the second direction is not less than 0.1, such as not less than 0.2, not less than 0.3, not less than 0.4, and not more than 0.5.

In some examples, as shown in FIG. 4 and FIG. 10A, the connection portion 510 and the two first electrodes 110 are configured as an integrated structure. For example, in the direction perpendicular to the base substrate 01, the connection portion 510 overlaps with the first signal line 310. For example, the first electrode layer 100 may be served as a common electrode layer, and there may be a plurality of connection portions 510 for connecting a plurality of first electrodes 110 arranged in the first direction. For example, the material of the common electrode layer may be a transparent conductive material, such as indium tin oxide (ITO). For example, the size of the connection portion 510 in the first direction may be greater than its size in the second direction. For example, the connection portion 510 may be a strip electrode extending in the first direction. For example, an edge of the connection portion 510 extending in the second direction is a portion of an edge of the first electrode 110 extending in the second direction. However, the present disclosure is not limited thereto, and a portion of the layer where the first electrode layer is located that overlaps with the first signal line may also be served as the connection portion, and the portions on two sides of the connection portion are served as the first electrodes.

In some examples, as illustrated in FIG. 4 and FIG. 10A, the number of the connection portion 510 provided between two adjacent first electrodes 110 in the first direction is at least one. For example, the sub-pixel 500 includes two sides close to the second signal lines 320 on the upper and lower sides of the sub-pixel 500, the connection portion 510 may be at a position close to at least one side of the two sides.

FIG. 10A schematically illustrates that one connection portion is provided between two adjacent first electrodes, but the embodiments are not limited to this configuration. FIG. 10B is a schematic diagram of a layer where a first electrode layer is located, provided by another example according to the embodiments of the present disclosure. As shown in FIG. 10B, two connection portions 511 and 512 may be provided between at least two adjacent first electrodes, for example, the two connection portions 511 and 512 are symmetrically distributed relative to a straight line that passes through the center of the first electrode and extends in the first direction. For example, the two connection portions 511 and 512 may be close to two second signal lines 320 on two sides of the first electrode 110, respectively, and a ratio of the minimum distances between the two connection portions 511 and 512 and the two second signal lines 320 ranges from 0.9 to 1.1. For example, the orthographic projections of the two connection portions 511 and 512 on the base substrate fall within the orthographic projection of the black matrix (described later) on the base substrate. Additionally, the two connection portions 511 and 512 may also be two structures asymmetrically distributed relative to a straight line that passes through the center of the first electrode and extends in the first direction; and the orthographic projections of the two connection portions 511 and 512 on the base substrate fall within the orthographic projection of the black matrix on the base substrate. By providing two or more first connection portions in the array substrate, it is beneficial to reducing the load of the display device without affecting the aperture ratio, reducing the risk of light leakage, and improving the electrical connection effect of adjacent first electrodes.

In some examples, as shown in FIG. 4, in the second direction, the distance between the first electrode 110 and the second signal line 320 is not greater than the distance between the connection portion 510 and the second signal line 320. For example, the ratio of the shortest distance between the first electrode 110 and the second signal line 320 to the shortest distance between the connection portion 510 and the same second signal line 320 may be 0.1-1, such as 0.3-0.8, 0.2-0.7, 0.4-0.9, or 0.5-0.6, etc. The distance between the connection portion and the second signal line may be set according to requirements. For example, an edge of the connection portion 510 that extends in the first direction and is closest to the second signal line 320 may be flush with at least a portion of an edge of the first electrode 110 that is closest to the same second signal line 320.

In some examples, as shown in FIG. 4 and FIG. 10A, in at least part of the sub-pixels 400, the first electrode includes a plurality of strip electrodes 111, for example, the plurality of strip electrodes 111 are spaced apart from each other. For example, at least part of the sub-pixels 400 includes multiple domains. By providing multiple domains in the same sub-pixel, the diversity of liquid crystal rotation directions in a display device adopting the array substrate is increased to alleviate the color shift issue of the display device at a wide viewing angle.

In some examples, as shown in FIG. 4 and FIG. 10A, in the same sub-pixel 400, the extension directions of the strip electrodes 111 in two adjacent domains intersect with each other. For example, at least part of the sub-pixels 400 includes two domains, and the extension direction of the strip electrode in each domain intersects with both the first direction and the second direction. However, the embodiments of the present disclosure are not limited to this; for example, at least part of the sub-pixels may include four domains, eight domains, etc. For another example, in at least part of the sub-pixels, at least part of the strip electrodes may be parallel to at least one of the first direction and the second direction.

For example, as shown in FIG. 4, in the first electrodes 110, in the integrated structure, of two adjacent sub-pixels, at least one strip electrode 111 in the first electrode 110 of one sub-pixel is on the same straight line as at least one strip electrode 111 in the first electrode 110 of another sub-pixel, and a separating portion extending in the second direction is provided in the middle of the first electrodes 110 of the two sub-pixels, and the separating portion is a part of the first common electrode line layer 121.

In some examples, as shown in FIG. 4 and FIG. 10A, the width of the connection portion 510 is greater than the width of the strip electrode 111, and the width of the connection portion 510 is not greater than 10 microns. For example, the width of the connection portion 510 is not greater than 9 microns. For example, the width of the connection portion 510 is not greater than 8 microns. For example, the width of the connection portion 510 may be 5 microns. For example, the width of the strip electrode 111 may be 2 microns.

In some examples, as illustrated in FIG. 4 and FIG. 10A, the width of the connection portion 510 is not less than the width of the strip electrode 111, and the width of the connection portion 510 is not greater than the minimum linewidth of the first signal line 310. By setting the width relationship of the connection portion, the first signal line, and the strip electrode, it is possible to achieve better electrical connection effect between adjacent first electrodes while minimizing the impact of the electric field generated at the connection portion on the deflection of liquid crystals, thereby preventing light leakage.

For example, as shown in FIG. 4 and FIG. 6, the shapes of two second signal lines 320 provided between two adjacent rows of sub-pixels (e.g., a plurality of sub-pixels arranged in the X direction may be a row of sub-pixels) are different, for example, the shapes of the two second signal lines at some positions are complementary to each other to enhance the compactness of the pixel arrangement in the array substrate.

For example, as shown in FIG. 4 and FIG. 8 to FIG. 10A, the array substrate further includes a plurality of common electrode lines 120, and the plurality of common electrode lines 120 are alternately arranged with a plurality of first signal lines 310 in the first direction. For example, the common electrode lines 120 include a first common electrode line layer 121 provided in the same layer as the first electrode 110. The first common electrode line layer 121 and the first electrode 110 are configured as an integrated structure, and are between adjacent sub-pixels 400. For example, the common electrode lines 120 further include a second common electrode line layer 122 provided in the same layer as the first signal line 310, and the first common electrode line layer 121 is electrically connected to the second common electrode line layer 122 through a via 362 in the insulating layer between the first common electrode line layer 121 and the second common electrode line layer 122. For example, a region defined by one common electrode line 120, one first signal line 310, and two second signal lines 320 arranged adjacently forms a pixel region where the sub-pixel 400 is located, and the region where the sub-pixel 400 is located is a region for displaying images.

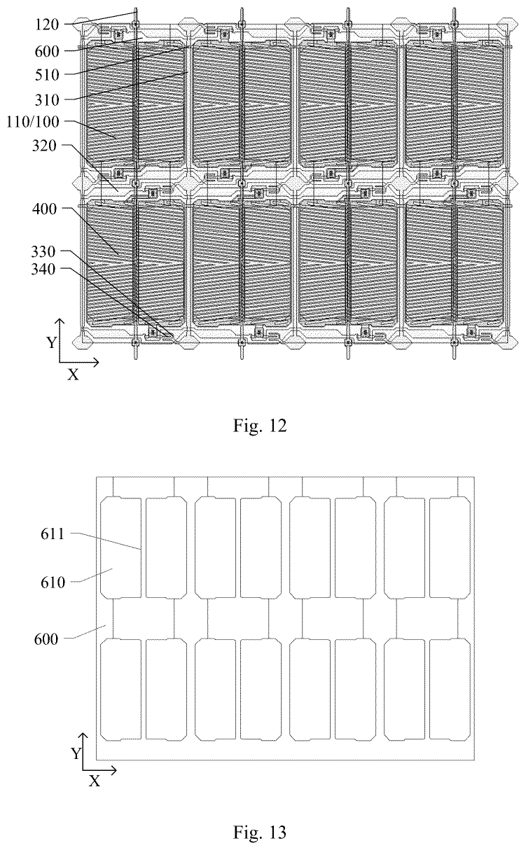

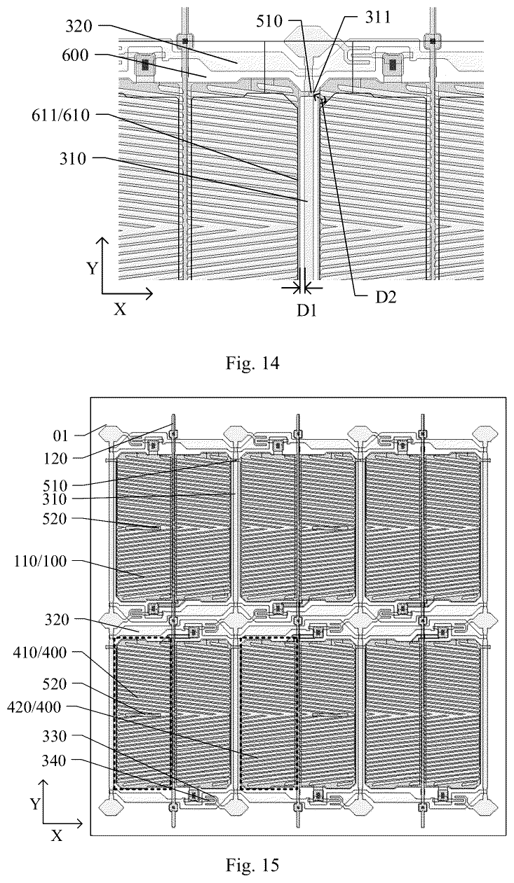

FIG. 11 is a partial structural diagram of a display device including the above-mentioned array substrate. FIG. 12 is a diagram showing a planar relationship between a black matrix and an array substrate in the display device shown in FIG. 11; FIG. 13 is a plan view of the black matrix in the display device shown in FIG. 11; and FIG. 14 is an enlarged view of a partial structure in FIG. 12. The array substrate shown in FIG. 11 may include the structure of the layer where the first electrode is located, as illustrated in FIG. 10A or FIG. 10B.

As shown in FIG. 11 to FIG. 14, the display device includes an array substrate 001 in any one of the above-mentioned examples and an opposite substrate 002 provided opposite to the array substrate 001. The opposite substrate 002 includes a light-shielding layer 600, and the light-shielding layer 600 includes a plurality of openings 610 to define light-emitting regions of sub-pixels 400. For example, the light-shielding layer 600 may be a black matrix. For example, the opposite substrate 002 may include a color filter layer (not shown) at the position of the openings 610, an alignment film (not shown) on the side of the black matrix facing the array substrate, and other structures.

For example, as illustrated in FIG. 11, the display device may be a liquid crystal display device, and a liquid crystal layer 003 is provided between the array substrate 001 and the opposite substrate 002.

As shown in FIG. 11 and FIG. 13, the orthographic projection of the first signal line 310 on the base substrate 01 includes a first orthographic projection, the orthographic projection of the connection portion 510 on the base substrate 01 includes a second orthographic projection, and the second orthographic projection is within the orthographic projection of the light-shielding layer 600 on the base substrate 01. For example, the connection portion 510 is completely covered by the light-shielding layer 600.

As shown in FIG. 12 to FIG. 14, the orthographic projection of the opening 610 on the base substrate 01 includes a third orthographic projection, and the distance between the edges, close to each other, of the first orthographic projection and the third orthographic projection is a first distance D1. The first orthographic projection includes an overlapping edge 311 overlapping with the second orthographic projection, the distance between the overlapping edge 311 and the closest edge of the third orthographic projection to the overlapping edge is a second distance D2, and the second distance D2 is greater than the first distance D1. For example, the minimum distance in the first direction between the edges, close to each other, of the first signal line 310 and the opening 610 is D1. For example, the distance between the position where the connection portion 510 overlaps with the first signal line 310 and an opening 610 closest to the connection portion 510 on the XY plane is the second distance D2.

For example, as shown in FIG. 12, the distance between the first electrode 110 and the first signal line 310 is greater than 5 microns, such as 5.5 microns-6 microns. The distance between the second electrode 210 and the first signal line 310 is greater than 5 microns, such as 5.5 microns-6 microns.

Compared with an array substrate in which the distance between the first electrode or the second electrode and the first signal line is 5 microns, the display device provided by the present disclosure increases the distance between the first electrode or the second electrode and the first signal line, while setting the position of the connection portion to a larger distance from the opening of the light-shielding layer, thereby reducing the load of the display device without affecting the aperture ratio. In this case, even if the black matrix has an alignment deviation, the risk of light leakage is still very low.

In some examples, as shown in FIG. 12 to FIG. 14, the first signal line 310 extends in the second direction. The opening 610 includes an opening edge 611 extending in the second direction and closest to the first signal line 310. The connection portion 510 is between the opening edge 611 and a second signal line 320 that is closest to the opening edge 611.

In some examples, as shown in FIG. 11, a straight line passing through the connection portion 510 and extending in the first direction does not pass through the opening edge 611. For example, the orthographic projection of the connection portion 510 on the straight line extending in the second direction does not overlap with the orthographic projection of the opening edge 611 on the straight line extending in the second direction. For example, the orthographic projection of the opening edge 611 on the base substrate 01 does not extend through a straight line passing through the orthographic projection of the connection portion 510 on the base substrate and extending in the first direction.

Setting the positional relationship between the connection portion and the opening edge is beneficial to increasing the distance between the connection portion and the opening edge, thereby reducing the risk of light leakage of the display device.

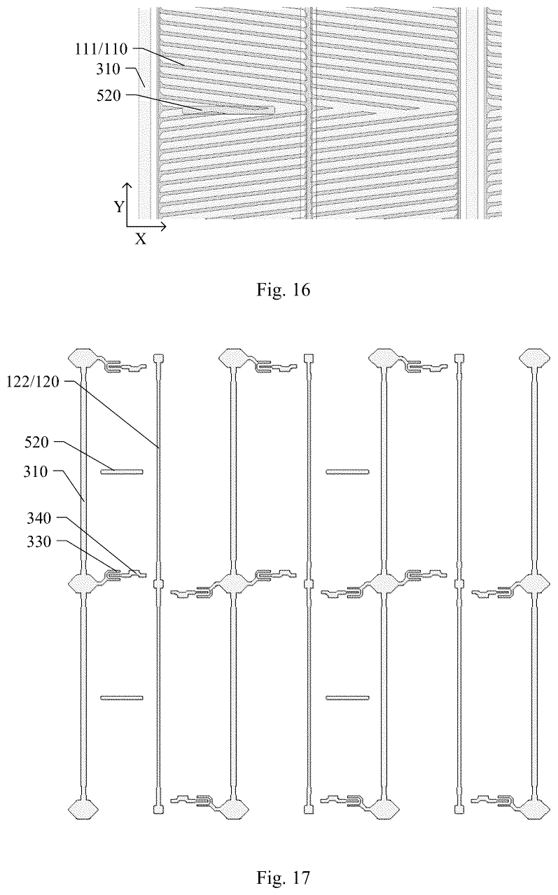

FIG. 15 is a schematic diagram of a partial planar structure of an array substrate provided by another example of the embodiments of the present disclosure; FIG. 16 is a partial enlarged view of the array substrate shown in FIG. 15; and FIG. 17 is a schematic diagram of a layer where a first signal line is located in the array substrate shown in FIG. 15. In an example of the array substrate shown in FIG. 15, other layers except the layer where the first signal line is located may have the same features as the layers of the array substrate shown in FIG. 4 to FIG. 10B, which will not be described in detail here.

In some examples, as shown in FIG. 15 to FIG. 17, the plurality of sub-pixels 400 include at least a first color sub-pixel 410 and a second color sub-pixel 420, and both the first color sub-pixel 410 and the second color sub-pixel 420 include multiple domains. For example, the first color sub-pixel 410 and the second color sub-pixel 420 may have the same number of domains. For example, both the first color sub-pixel 410 and the second color sub-pixel 420 include two domains. However, the present disclosure is not limited thereto, and the first color sub-pixel and the second color sub-pixel may each include four domains, eight domains, etc.

In some examples, as shown in FIG. 15 to FIG. 17, a protrusion portion 520 is provided in a light-emitting region of one of the first color sub-pixel 410 and the second color sub-pixel 420, and the protrusion portion 520 is between two adjacent domains among the multiple domains. For example, the number of the multiple domains may be two, the two domains are arranged in the second direction, and the protrusion portion 520 is provided between the two domains.

In some examples, as shown in FIG. 15 to FIG. 17, one of the first color sub-pixel 410 and the second color sub-pixel 420 is a red sub-pixel, and the other is a blue sub-pixel. For example, the sub-pixel with the protrusion portion 520 in the light-emitting region may be a red sub-pixel or a blue sub-pixel.

The polarizer (POL) of a display device adopting negative liquid crystals has different absorption rates for red light and blue light, which may easily lead to issues of color shift at large viewing angles, such as blue deviation at large viewing angles or red deviation at large viewing angles.

Taking the case where the sub-pixel with a protrusion portion in the light-emitting region is a red sub-pixel as an example, relative to a display device without a protrusion portion, such as a display device that will occur blue deviation at a large viewing angle during display, the array substrate provided by the present disclosure provides a protrusion portion in the light-emitting region of the red sub-pixel, so that during the alignment process, an alignment abnormality occurs in the alignment film at the position corresponding to the protrusion portion, thereby making it impossible for the liquid crystal to be normally aligned at the position corresponding to the protrusion portion and leaking a small amount of red light. The small amount of leaked red light can neutralize part of the blue light, thereby reducing the effect of the blue deviation of the display device at a large viewing angle.

Taking the case where the sub-pixel with a protrusion portion in the light-emitting region is a blue sub-pixel as an example, relative to a display device without a protrusion portion, such as a display device that will occur red deviation at a large viewing angle during display, the array substrate provided by the present disclosure provides a protrusion portion in the light-emitting region of the blue sub-pixel, so that during the alignment process, an alignment abnormality occurs in the alignment film at the position corresponding to the protrusion portion, thereby making it impossible for the liquid crystal to be normally aligned at the position corresponding to the protrusion portion and leaking a small amount of blue light. The small amount of leaked blue light can neutralize part of the red light, thereby reducing the effect of the red deviation of the display device at a large viewing angle.

For example, as shown in FIG. 15 to FIG. 17, the light-emitting region of the first color sub-pixel 410 is provided with a protrusion portion 520, and the light-emitting region of the second color sub-pixel 420 is not provided with the protrusion portion 520. The number of the first color sub-pixels 410 is multiple, and the light-emitting region of at least one first color sub-pixel 410 is provided with a protrusion portion 520. For example, the light-emitting region of each first color sub-pixel 410 is provided with a protrusion portion 520, the number of protrusion portions 520 is multiple, and the protrusions 520 are evenly distributed.

For example, as shown in FIG. 15, the plurality of sub-pixels 400 further include a third color sub-pixel, and the third color sub-pixel may be a green sub-pixel. For example, the light-emitting region of the green sub-pixel is not provided with a protrusion portion.

In some examples, as shown in FIG. 15 and FIG. 16, in the direction perpendicular to the base substrate 01, the protrusion portion 520 overlaps with the strip electrode 111 in at least one of two adjacent domains, or the protrusion portion 520 does not overlap with the strip electrode 111. For example, the protrusion portion 520 includes a plurality of sub-portions, each of the sub-portions overlaps only with the spacing between adjacent strip electrodes 111.

In some examples, as shown in FIG. 15 and FIG. 16, in the direction perpendicular to the base substrate 01, the edge of the protrusion portion 520 does not overlap with the light-emitting region of the adjacent sub-pixel 400, to prevent affecting the light-emitting region of the sub-pixel 400 adjacent to the sub-pixel 400 where the protrusion portion 520 is located. For example, the edge of the protrusion portion 520 is within the light-emitting region of the sub-pixel 400. However, the present disclosure is not limited thereto, and the edge of the protrusion portion may also overlap with the black matrix. For example, the size of the protrusion portion 520 in the first direction is greater than 1 micron. For example, the size of the protrusion portion 520 in the first direction is greater than 1.5 microns.

In some examples, as shown in FIG. 15 and FIG. 16, the size of the protrusion portion 520 in the arrangement direction of two adjacent domains ranges from 1.5 micron to 6 microns.

For example, the size of the protrusion portion 520 in the arrangement direction of two adjacent domains is not greater than 4.8 microns. For example, the size of the protrusion portion 520 in the arrangement direction of two adjacent domains is not greater than 4.5 microns. For example, the size of the protrusion portion 520 in the arrangement direction of two adjacent domains is not greater than 4 microns. For example, the size of the protrusion portion 520 in the arrangement direction of two adjacent domains is 2 microns. For example, the size of the protrusion portion 520 in the arrangement direction of two adjacent domains is 2.5 microns. For example, the size of the protrusion portion 520 in the arrangement direction of two adjacent domains is 3 microns.

For example, as shown in FIG. 15 and FIG. 16, the extension direction of the protrusion portion 520 intersects with the arrangement direction of two adjacent domains on two sides of the protrusion portion 520. For example, the protrusion portion 520 extends in the first direction, and the two adjacent domains are arranged in the second direction. For example, the size of the protrusion portion 520 in the first direction is not greater than the size of the light-emitting region where the protrusion portion 520 is located in the first direction.

Setting the size and position of the protrusion portion is beneficial to achieving a certain amount of light leakage from the sub-pixel where the protrusion portion is located, thereby neutralizing light of another color to alleviate the color shift phenomenon at a large viewing angle.

For example, FIG. 15 and FIG. 16 schematically illustrate that the number of the protrusion portion provided in the same light-emitting region is one, but the embodiments are not limited to this. The number of protrusion portions provided in the same light-emitting region may be multiple, such as two, three or more, and two ends of the protrusion portions located at the outermost edge do not exceed the edge of the light-emitting region.

In some examples, as shown in FIG. 15 to FIG. 17, the protrusion portion 520 is provided in the same layer as one of the first signal line 310 and the second signal line 320. For example, the protrusion portion 520 is provided in the same layer as the first signal line 310. For example, the protrusion portion 520 is not electrically connected to any signal line and may be in a floating state.

Of course, the embodiments of the present disclosure are not limited to this case, and the protrusion portion may also be provided in the same layer as the second signal line. In other examples, the protrusion portion may also be a part of an insulating layer, such as forming a protrusion portion with a thickness greater than that of other positions in the insulating layer through a half-tone mask process.

The embodiments of the present disclosure schematically show that the second electrode layer and the second signal line are provided in different layers, but the present disclosure is not limited thereto. The second electrode layer may also be provided in the same layer as the second signal line, and in this case, the protrusion portion is provided in the same layer as the first signal line. For example, the second electrode is provided in the same layer as one of the first signal line and the second signal line, and the protrusion portion is provided in the same layer as the other one of the first signal line and the second signal line.

It should be noted that a dual-gate structure is illustrated in the present disclosure, and such a configuration can reduce the number of data lines. Of course, the present disclosure may also adopt a single-gate structure, that is, the same row of gate line corresponds to one row of sub-pixels, and two adjacent columns of sub-pixels are connected to different data lines. The specific display architecture is not limited in the present disclosure.

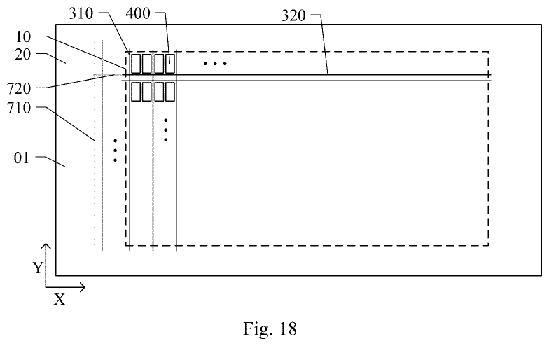

FIG. 18 is a schematic diagram of a planar structure of an array substrate provided by the embodiments of the present disclosure. The array substrate shown in FIG. 18 may include an array substrate in any one of the above-mentioned examples.

In some examples, as shown in FIG. 18, the array substrate includes a display region 10 and a non-display region 20 on at least one side of the display region 10, and a plurality of sub-pixels 400, a plurality of first signal lines 310, and a plurality of second signal lines 320 are all in the display region 10.

In some examples, as shown in FIG. 18, the array substrate further includes a plurality of signal transmission lines 710 in the non-display region 20 and provided in the same layer as the second signal line 320, and includes connection lines 720 electrically connected to the signal transmission lines 710. The connection lines 720 extend in the first direction, the signal transmission lines 710 extend in the second direction, and the connection lines 720 are provided in the same layer as the first signal line 310. For example, the signal transmission line 710 is electrically connected to the second signal line 320 through the connection line 720.

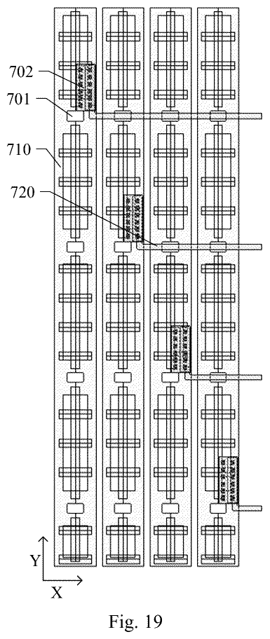

FIG. 19 is a schematic diagram of signal transmission lines and connection lines in an array substrate.

During the research, the inventor(s) of the present disclosure found that: as shown in FIG. 19, the connection line 720 realizes the electrical connection between the signal transmission line 710 and the connection line 720 through a transfer portion 702. At least one connection line 720 needs to cross the signal transmission line 710 located between the connection line 720 and the display region, to be electrically connected to a corresponding second signal line 320. An opening 701 is provided at the position crossed by the connection line 720 to reduce the overlapping area between the two, thereby reducing the load of the signal line. However, the connection line 720 is on a side of the signal transmission line 710 away from the base substrate, and the connection line 720 needs to climb twice to cross a signal transmission line 710. The more signal transmission lines 710 that the connection line 720 crosses, the more times the connection line 720 climbs, which not only affects the flatness at the non-display region, but also easily leads to the risk of the connection line being broken.

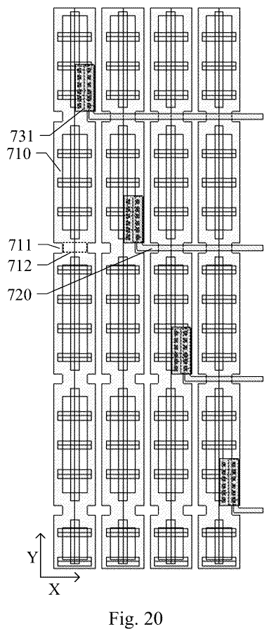

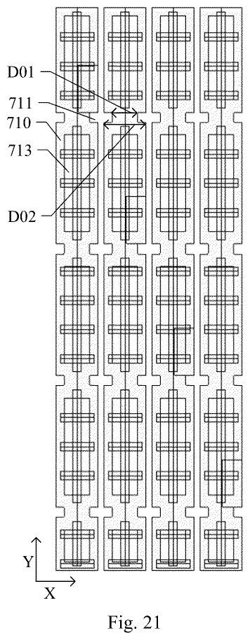

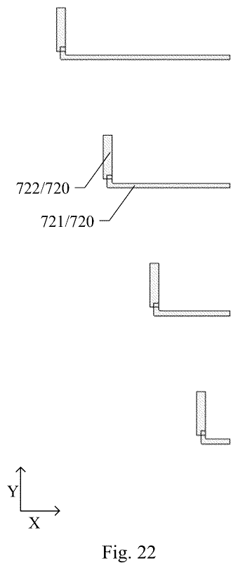

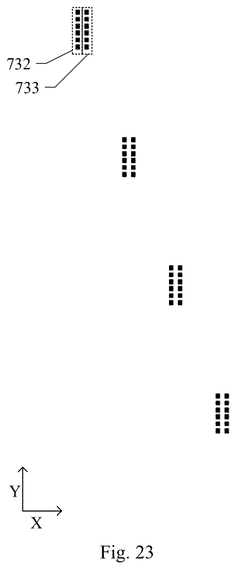

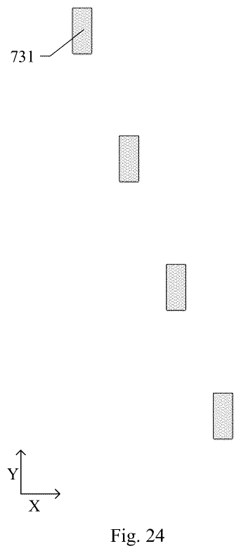

FIG. 20 is a schematic diagram of the signal transmission lines, connection lines, and connection structures provided by the embodiments of the present disclosure; FIG. 21 is a schematic diagram of the signal transmission lines shown in FIG. 20; FIG. 22 is a schematic diagram of the connection lines shown in FIG. 20; and FIG. 23 and FIG. 24 are schematic diagrams of vias and connection structures shown in FIG. 20.

In some examples, as shown in FIG. 18 and FIG. 20 to FIG. 24, in a direction perpendicular to the base substrate 01, at least one signal transmission line 710 overlaps with the connection line 720, and an edge of an overlapping portion of the signal transmission line 710 with the connection line 720 includes a notch 711, so that the size of the overlapping portion in the extension direction of the connection line 720 is smaller than the size of at least part, except for the overlapping portion, of the signal transmission line 710 in the extension direction of the connection line 720. For example, the signal transmission lines 710 may include a clock signal line for providing clock signals to a gate driving circuit provided in a non-display region of a display panel, and the gate driving circuit is used to be electrically connected with gate lines of a display region of the display panel. Optionally, the signal transmission lines may also include a signal line for providing a direct-current signal for the gate driving circuit; for example, the direct-current signal includes a VGH or VGL signal, or may also include an initial signal (STV) for the gate driving circuit, etc., which is not limited here.

For example, as shown in FIG. 21, the size of the overlapping portion in the first direction is D01, and the size of a portion outside the overlapping portion and closest to the overlapping portion in the first direction is D02. For example, D02 may be the line width of the signal transmission line 710 (the size of the position where the width is the largest in the first direction), and D01 is smaller than D02. For example, the ratio of D01 to D02 may be 0.1-0.9, such as 0.3-0.8, such as 0.4-0.6 to balance the capacitance and resistance.

Compared with the solution shown in FIG. 19 of providing an opening at the overlapping position of the signal transmission line and the connection wire, the array substrate provided by the present disclosure provides a notch at an edge of the overlapping portion of the signal transmission line with the connection line, so that the number of times the connection line climbs when crossing the signal transmission line can be reduced without changing the resistance and capacitance, thereby reducing the risk of the connection line being broken.

For example, as shown in FIG. 20 to FIG. 24, the connection line 720 is connected to a connection structure 731 through vias 733 in an insulating layer between the connection line 720 and the connection structure 731, and the signal transmission line 710 is connected to the connection structure 731 through vias 732 in an insulating layer between the signal transmission line 710 and the connection structure 731, thereby realizing the connection between the connection line 720 and the signal transmission line 710. For example, the connection structure 731 is provided in the same layer as one of the first electrode layer and the second electrode layer. For example, the number of vias 733 may be multiple, and the number of vias 732 may be multiple.

For example, as shown in FIG. 20, each signal transmission line 710 includes a plurality of notches 711, and two edges of the signal transmission line 710 extending in the second direction are provided with notches 711, and the plurality of notches 711 are symmetrically distributed relative to a center line of each signal transmission line 710 extending in the second direction.

For example, referring to FIG. 20, the signal transmission line is electrically connected to the connection line through the connection structure, and at the position of the connection structure, a connection part between the connection line and the connection structure is at least partially provided at the notch.

For example, as shown in FIG. 20, the number of signal transmission lines 710 is multiple, and notches 711 in different signal transmission lines 710 have the same distribution to facilitate manufacturing.

For example, as shown in FIG. 20, a portion of the signal transmission line 710 between two notches 711 arranged in the first direction is a narrowing portion 712. For example, at least one signal transmission line 710 includes a plurality of narrowing portions 712, and the plurality of narrowing portions 712 are uniformly arranged in the second direction.

For example, as shown in FIG. 20, at least one narrowing portion 712 of at least one signal transmission line 710 does not overlap with the connection line 720. For example, each narrowing portion 712 of at least one signal transmission line 710 does not overlap with the connection line 720. For example, the number of a plurality of narrowing portions 712 of at least one signal transmission line 710 that overlap with the connection line 720 may be less than, equal to, or greater than the number of a plurality of narrowing portions 712 that do not overlap with the connection line 720.

For example, as shown in FIG. 20 and FIG. 22, the connection line 720 includes a first connection line portion 721 extending in the first direction and a second connection line portion 722 extending in the second direction, and the first connection line portion 721 and the second connection line portion 722 may be an integrated structure. For example, a corner formed by the first connection line portion 721 and the second connection line portion 722 overlaps with the notch 711. For example, a corner formed by the first connection line portion 721 and the second connection line portion 722 does not overlap with the signal transmission line 710.

For example, as shown in FIG. 20 and FIG. 21, part of at least some of the signal transmission lines 710 not overlapping the connection line 720 are provided with slots 713. For example, a plurality of slots 713 are provided between adjacent narrowing portions 712. For example, the plurality of slots 713 between adjacent narrowing portions 712 are arranged in an array in the first direction and the second direction.

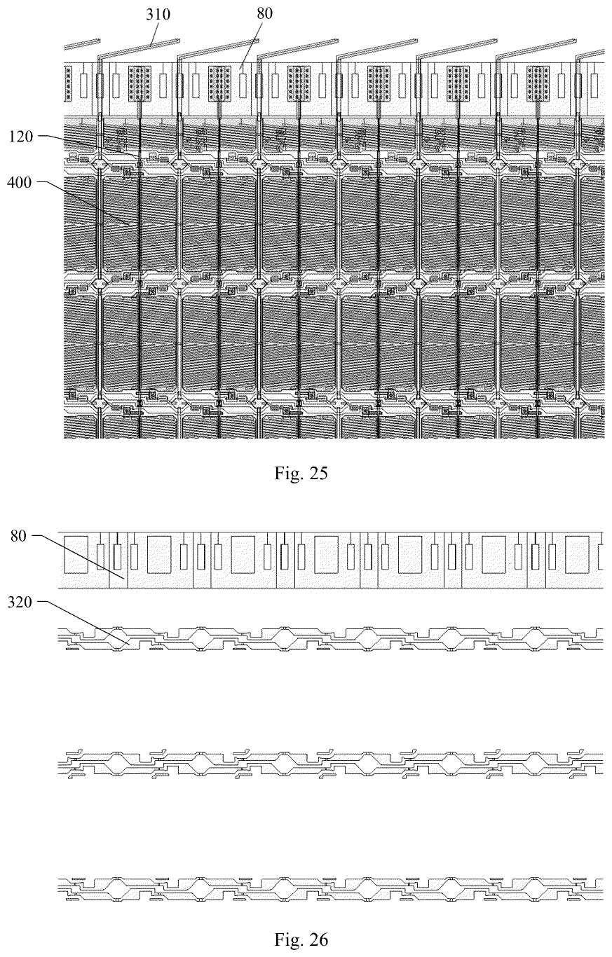

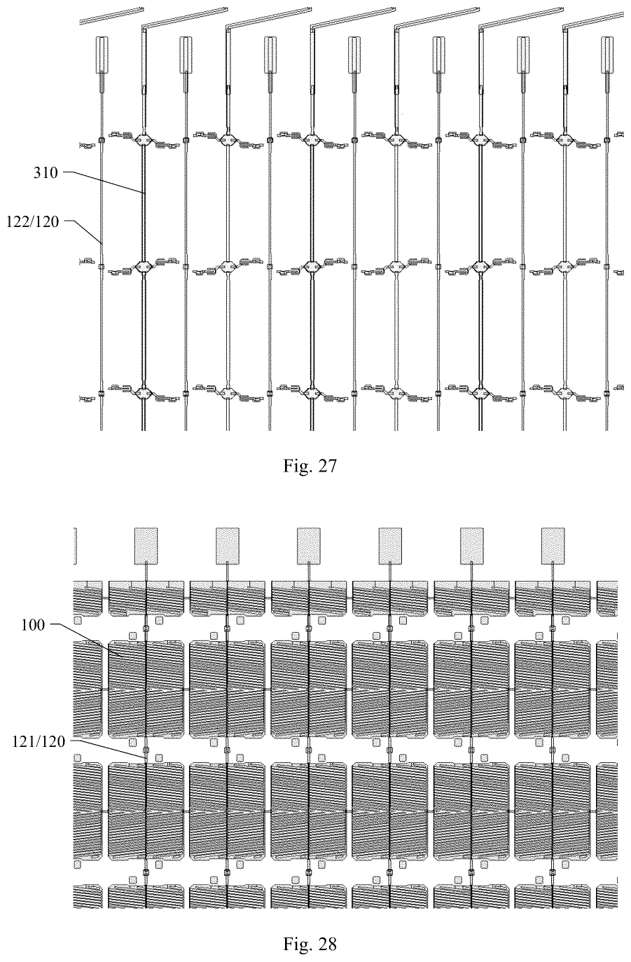

FIG. 25 is a schematic diagram of a partial planar structure of an array substrate. FIG. 26 to FIG. 28 are schematic diagrams of different layers in the array substrate shown in FIG. 25.

As shown in FIG. 25 to FIG. 28, the array substrate may include the sub-pixels 400, the first signal lines 310, the second signal lines 320, and the common electrode lines 120 in the above-mentioned embodiments, the sub-pixels 400 share the first electrode layer 100, and the above-mentioned sub-pixels 400, the first signal lines 310, the second signal lines 320, and the common electrode lines 120 are all in the display region. The array substrate shown in FIG. 25 to FIG. 28 further includes a common signal transmission line 80 in the non-display region, and each common electrode line 120 is electrically connected to the same common signal transmission line 80.

During the research, the inventor(s) of the present disclosure found that the display device may be a liquid crystal display device. With the continuous improvement of the light efficiency of the liquid crystal, the content of the large polar monomer in the liquid crystal continues to increase. Due to the influence of the large polar monomer component in the liquid crystal included in the liquid crystal layer, linear stain issues are likely to occur at the overlapping position of black and white images when the display device continuously shows a checkerboard image or other similar black-and-white grid images for a long period.

The embodiments of the present disclosure provide an array substrate, and the array substrate includes a base substrate and a plurality of sub-pixels, a plurality of data lines and a plurality of common electrode lines on the base substrate. The base substrate includes a display region and a first non-display region on at least one side of the display region; the plurality of sub-pixels are in the display region, and each sub-pixel includes a first electrode and a second electrode stacked with each other; the plurality of data lines are in the display region and configured to be electrically connected to second electrodes, and the plurality of data lines are arranged in a first direction; the plurality of gate lines are in the display region and arranged in a second direction, and the second direction intersects with the first direction; and the plurality of common electrode lines are in the display region and electrically connected to first electrodes, and the plurality of common electrode lines and the plurality of data lines are alternately arranged in the first direction. The array substrate further includes a common signal transmission line in the first non-display region, and the common signal transmission line includes a first common signal transmission line and a second common signal transmission line; the second common signal transmission line is provided on a side of the first common signal transmission line away from the display region, and the common signal transmission line extends in the first direction; the first common signal transmission line is electrically connected to a part of the plurality of common electrode lines, and the second common signal transmission line is electrically connected to another part of the common electrode lines; and the first non-display region further includes a pad region configured to be electrically connected to a circuit board. By providing the first common signal transmission line and the second common signal transmission line, the array substrate provided by the present disclosure is beneficial to reducing or eliminating issues such as non-uniform display brightness and linear mura.

In some examples, the first common signal transmission line and the second common signal transmission line are configured to transmit different electrical signals. Providing the first common signal transmission line and the second common signal transmission line that transmit different electrical signals is beneficial to reducing or eliminating issues such as non-uniform display brightness and linear mura.

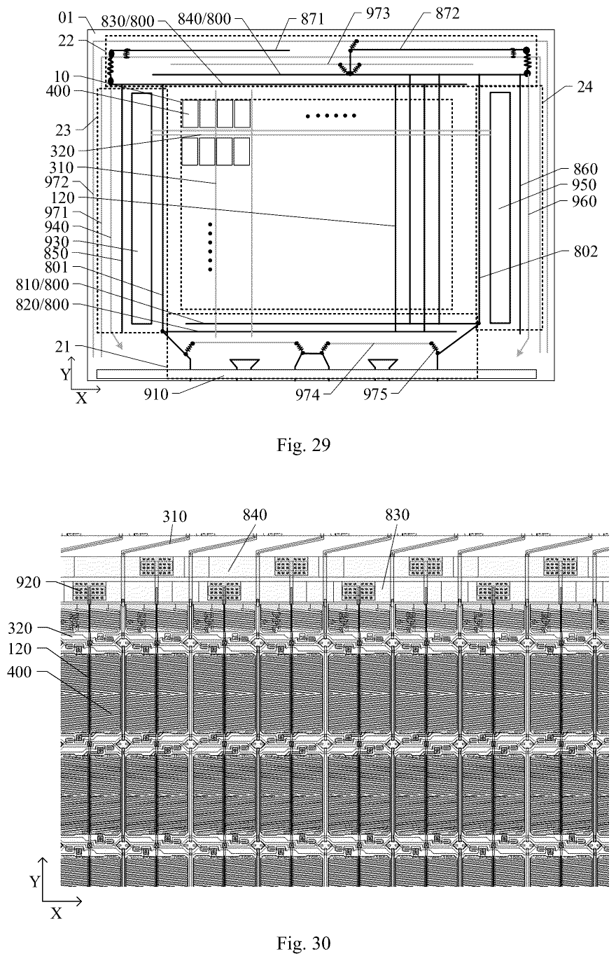

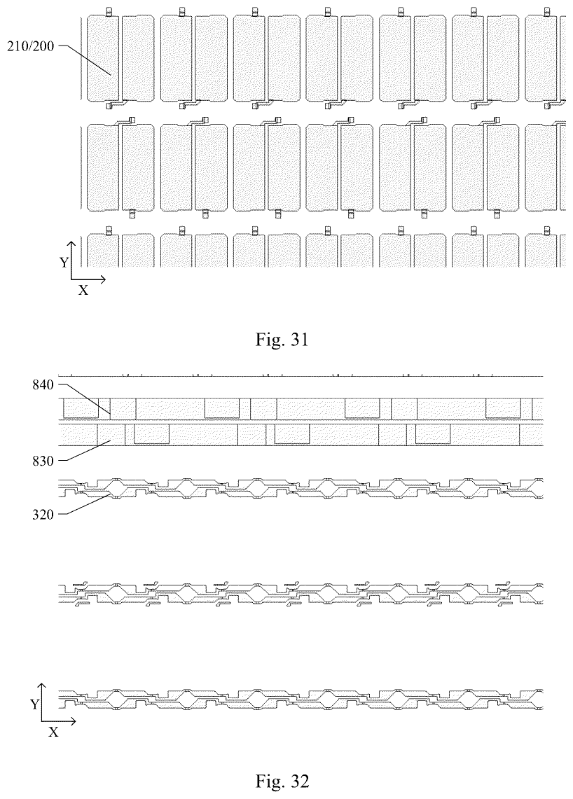

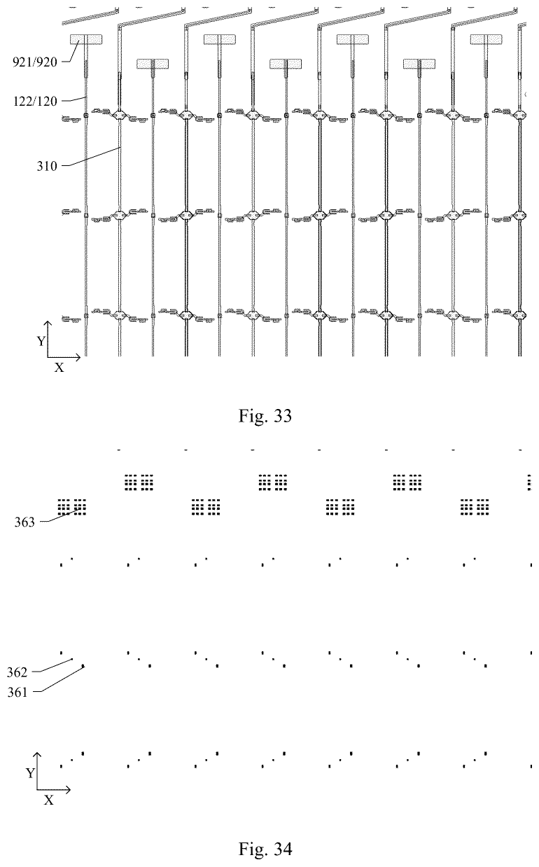

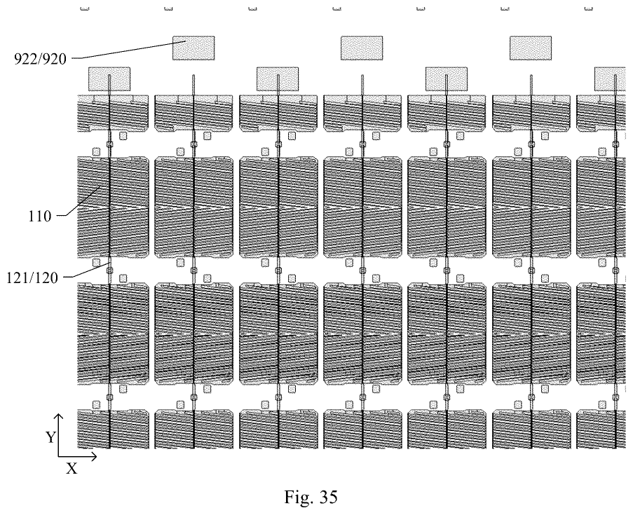

FIG. 29 is a schematic diagram of a planar structure of an array substrate provided by the embodiments of the present disclosure; FIG. 30 is a partial enlarged view of a display region and a second non-display region in the array substrate shown in FIG. 29; FIG. 31 is a schematic diagram of a layer where a second electrode of a sub-pixel is located in the array substrate shown in FIG. 30; FIG. 32 is a schematic diagram of a layer where a gate line is located in the array substrate shown in FIG. 30; FIG. 33 is a schematic diagram of a layer where a data line is located in the array substrate shown in FIG. 30; FIG. 34 is a schematic diagram of vias in the array substrate shown in FIG. 30; and FIG. 35 is a schematic diagram of a layer where a first electrode of a sub-pixel is located in the array substrate shown in FIG. 30.

As shown in FIG. 29, the array substrate includes a base substrate 01, and the base substrate 01 includes a display region 10 and a first non-display region 21 on at least one side of the display region 10. The array substrate includes a plurality of sub-pixels 400, a plurality of data lines 310, a plurality of gate lines 320, and a plurality of common electrode lines 120 on the base substrate 01. The plurality of sub-pixels 400, the plurality of data lines 310, the plurality of gate lines 320, and the plurality of common electrode lines 120 are all in the display region 10.

As shown in FIG. 29 to FIG. 31 and FIG. 34, each sub-pixel 400 includes a first electrode 110 and a second electrode 210 stacked with each other. The second electrode 210 included in the sub-pixel 400 in the array substrate shown in FIG. 29 to FIG. 34 may have the same features as the second electrode 210 included in the sub-pixel 400 in the array substrate shown in FIG. 4 to FIG. 17, and will not be repeated here.

As shown in FIG. 29, FIG. 30, FIG. 32 and FIG. 33, the plurality of data lines 310 are configured to be electrically connected to second electrodes 210 of sub-pixels 400, and the plurality of data lines are arranged in the first direction. The plurality of gate lines 320 are arranged in the second direction, and the second direction intersects with the first direction.

In some examples, as shown in FIG. 29 to FIG. 35, two gate lines 320 are provided between two adjacent sub-pixels 400 arranged in the second direction, two sub-pixels 400 arranged in the first direction are provided between two adjacent data lines 310, and the first electrodes 110 of two sub-pixels 400 are configured as an integrated structure.

The data lines 310 in the array substrate shown in FIG. 29 to FIG. 35 have the same features as the first signal lines 310 in the array substrate shown in FIG. 4 to FIG. 17, and the gate lines 320 in the array substrate shown in FIG. 29 to FIG. 35 has the same features as the second signal lines 320 in the array substrate shown in FIG. 4 to FIG. 17, which will not be repeated here. The first direction and the second direction in the array substrate shown in FIG. 29 to FIG. 35 can refer to the first direction and the second direction in the array substrate shown in FIG. 4 to FIG. 17, which will not be repeated here. The positional relationship between the sub-pixels 400, the data lines 310 and the gate lines 320 in the array substrate shown in FIG. 29 to FIG. 35 can refer to the positional relationship between the sub-pixels 400, the data lines 310 and the gate lines 320 in the array substrate shown in FIG. 4 to FIG. 17.

For example, the array substrate shown in FIG. 29 to FIG. 35 further includes the transistors in the array substrate shown in FIG. 4 to FIG. 17, and the connection relationship between the transistors and the data lines, the gate lines and the first electrodes of sub-pixels can refer to the corresponding connection relationship in the array substrate shown in FIG. 4 to FIG. 17.

As shown in FIG. 29, FIG. 30, FIG. 33 and FIG. 35, a plurality of common electrode lines 120 are electrically connected to first electrodes 110 of sub-pixels 400, and the plurality of common electrode lines 120 and the plurality of data lines 310 are alternately arranged in the first direction.

In some examples, as shown in FIG. 29, FIG. 30, FIG. 33 and FIG. 35, at least one common electrode line 120 includes a first conductive layer 122 and a second conductive layer 121 stacked with each other, the first conductive layer 122 is provided in the same layer as the data line 310, and the second conductive layer 121 is provided in the same layer as the first electrode 110.

The first conductive layer 122 of the common electrode line 120 shown in FIG. 33 has the same features as the second common electrode line layer 122 of the common electrode line 120 shown in FIG. 8, and the first conductive layer 122 of the common electrode line 120 shown in FIG. 33 can refer to the relevant description of the second common electrode line layer 122 of the common electrode line 120 shown in FIG. 8. The second conductive layer 121 of the common electrode line 120 shown in FIG. 35 has the same features as the first common electrode line layer 121 of the common electrode line 120 shown in FIG. 10A or FIG. 10B, and the second conductive layer 121 of the common electrode line 120 shown in FIG. 35 can refer to the relevant description of the first common electrode line layer 121 of the common electrode line 120 shown in FIG. 10A or FIG. 10B.

As shown in FIG. 29, the array substrate further includes a common signal transmission line 800 in the first non-display region 21, the common signal transmission line 800 includes a first common signal transmission line 810 and a second common signal transmission line 820, the second common signal transmission line 820 is provided on a side of the first common signal transmission line 810 away from the display region 10, and the common signal transmission line 800 extends in the first direction. For example, the first common signal transmission line 810 and the second common signal transmission line 820 are arranged in parallel.

As shown in FIG. 29, the first common signal transmission line 810 and the second common signal transmission line 820 are configured to transmit different electrical signals, the first common signal transmission line 810 is electrically connected to a part of the plurality of common electrode lines 120, and the second common signal transmission line 820 is electrically connected to another part of the plurality of common electrode lines 120. For example, the number of the plurality of common electrode lines 120 is N, M common electrode lines 120 are electrically connected to the first common signal transmission line 810, and (N−M) common electrode lines 120 are electrically connected to the second common signal transmission line 820; and both M and N are positive integers, and M is less than N. For example, the number of common electrode lines 120 electrically connected to the first common signal transmission line 810 is equal to the number of common electrode lines 120 electrically connected to the second common signal transmission line 820. However, the present disclosure is not limited thereto, and the number of common electrode lines electrically connected to the first common signal transmission line and the number of common electrode lines electrically connected to the second common signal transmission line may be different according to display requirements.

As shown in FIG. 29, the first non-display region 21 further includes a pad region 910, and the pad region 910 is configured to be electrically connected to a circuit board. For example, the second common signal transmission line 820 is between the first common signal transmission line 810 and the pad region 910. For example, the pad region 910 includes a plurality of pads electrically connected to the circuit board. For example, the circuit board may be a flexible printed circuit (FPC), a printed circuit board (PCB), etc.

The array substrate provided by the present disclosure provides the first common signal transmission line and the second common signal transmission line that transmit different electrical signals, to reduce the degree of non-uniform brightness when a display device including the array substrate displays by flexibly adjusting the difference in the electrical signals transmitted by the first common signal transmission line and the second common signal transmission line.

In some examples, as shown in FIG. 29 and FIG. 30, the array substrate further includes a second non-display region 22, and the first non-display region 21, the display region 10, and the second non-display region 22 are arranged sequentially in the second direction. For example, the first non-display region 21 and the second non-display region 22 are on two sides of the display region 10 in the second direction. The common signal transmission line 800 further includes a third common signal transmission line 830 and a fourth common signal transmission line 840 both in the second non-display region 22, the fourth common signal transmission line 840 is on a side of the third common signal transmission line 830 away from the display region 10, the third common signal transmission line 830 is electrically connected to the second common signal transmission line 820, and the fourth common signal transmission line 840 is electrically connected to the first common signal transmission line 810.

In some examples, as shown in FIG. 29, FIG. 30 and FIG. 32, at least part of the common signal transmission line 800 is provided in the same layer as the gate line 320. For example, the first common signal transmission line 810, the second common signal transmission line 820, the third common signal transmission line 830, and the fourth common signal transmission line 840 are provided in the same layer. For example, the third common signal transmission line 830 is arranged in parallel with the fourth common signal transmission line 840.

For example, as shown in FIG. 29, two ends of at least one common electrode line 120 are connected to the first common signal transmission line 810 and the fourth common signal transmission line 840, respectively; and two ends of at least one common electrode line 120 are connected to the second common signal transmission line 820 and the third common signal transmission line 830, respectively.

In some examples, as shown in FIG. 29, the array substrate further includes a third non-display region 23 and a fourth non-display region 24, and the third non-display region 23, the display region 10, and the fourth non-display region 24 are arranged sequentially in the first direction. For example, the display region 10 is between the third non-display region 23 and the fourth non-display region 24. For example, the first non-display region 21, the second non-display region 22, the third non-display region 23, and the fourth non-display region 24 form a circle of non-display regions surrounding the display region 10.

In some examples, as shown in FIG. 29, the third non-display region 23 is provided with a first connection line 801 to connect the second common signal transmission line 820 and the third common signal transmission line 830, the fourth non-display region 24 is provided with a second connection line 802 to connect the first common signal transmission line 810 and the fourth common signal transmission line 840, and at least a portion of the first connection line 801, at least a portion of the second connection line 802, and at least a portion of the common signal transmission line 800 are provided in the same layer. For example, the first common signal transmission line 810, the fourth common signal transmission line 840, and the second connection line 802 are configured as an integrated structure, and the second common signal transmission line 820, the third common signal transmission line 830, and the first connection line 801 are configured as an integrated structure. Of course, the embodiments of the present disclosure are not limited to this, and at least one of the first connection line and the second connection line may also be connected to the common signal transmission line through other transfer layers.

In some examples, as shown in FIG. 29, FIG. 30, and FIG. 35, first electrodes 110 of two columns of sub-pixels 400 being between adjacent data lines 310 are electrically connected to the same common electrode line 120; and first electrodes 110 of two columns of sub-pixels 400 that are on two sides of the same data line 310 and closest to the same data line 310 are spaced apart from each other, and are electrically connected to the first common signal transmission line 810 and the second common signal transmission line 820, respectively. For example, first electrodes 110 of two sub-pixels 400 that are on two sides of the data line 310 and arranged in the first direction are insulated from each other, to be electrically connected to the third common signal line 830 and the fourth common signal line 840, respectively. The rows and columns in the present disclosure may be interchangeable.

For example, as shown in FIG. 29, FIG. 30 and FIG. 35, the odd-numbered common electrode line 120 among the plurality of common electrode lines 120 is electrically connected to one of the third common signal transmission line 830 and the fourth common signal transmission line 840, and the even-numbered common electrode line 120 is electrically connected to the other one of the third common signal transmission line 830 and the fourth common signal transmission line 840. Leading out the odd-numbered and even-numbered common electrode lines separately and obtaining two independent common level voltages from an external circuit make it possible to set different levels according to the position of the linear stain, thereby finely adjusting the pixel brightness at the black-white boundary to reduce or eliminate issues such as the linear stain.

Of course, the embodiments of the present disclosure are not limited to this, and the connection relationship between the common electrode lines and the common signal transmission lines can be set according to actual needs, for example, dividing a plurality of common electrode lines into groups, each group includes at least two common electrode lines that are adjacently arranged, and each group of common electrode lines is connected to the same common signal transmission line. For example, the number of common electrode lines in different groups may be the same or different. The odd-even separation of the common electrode lines is not limited to the plurality of common electrode lines arranged in the first direction mentioned above. When the common electrode lines are arranged in the second direction, common electrode lines of odd and even rows may also be separated.

In some examples, as shown in FIG. 29, FIG. 30, FIG. 33 and FIG. 35, the array substrate further includes a transfer portion 920, and at least one common electrode line 120 is electrically connected to the common signal transmission line 800 through the transfer portion 920. The transfer portion 920 includes a first transfer layer 921 and a second transfer layer 922 stacked with each other, the first transfer layer 921 is provided in the same layer as the first conductive layer 122, and the second transfer layer 922 is provided in the same layer as the second conductive layer 121.

For example, as shown in FIG. 33, the first transfer layer 921 and the first conductive layer 122 are configured as an integrated structure.

For example, as shown in FIG. 35, a portion of the second transfer layer 922 and the second conductive layer 121 are configured as an integrated structure, and the portion of the second transfer layer 922 is connected to the third common signal transmission line 830; and another portion of the second transfer layer 922 is spaced apart from the second conductive layer 121, and this portion of the second transfer layer 922 is connected to the fourth common signal transmission line 840.

For example, as shown in FIG. 30 to FIG. 35, the second transfer layer 922 is electrically connected to the first transfer layer 921 through a part of a plurality of vias 363, and the first transfer layer 921 is connected to the third common signal transmission line 830 and the fourth common signal transmission line 840 through another part of the plurality of vias 363.

For example, as shown in FIG. 32, the size of a spacing between the third common signal transmission line 830 and the fourth common signal transmission line 840 is smaller than the width of at least one of the third common signal transmission line 830 and the fourth common signal transmission line 840. For example, a ratio of the width of the third common signal transmission line 830 to the width of the fourth common signal transmission line 840 is 0.9-1.1, for example, the width of the third common signal transmission line 830 is equal to the width of the fourth common signal transmission line 840.

For example, at least one of the third common signal transmission line 830 and the fourth common signal transmission line 840 may be provided with a plurality of slots (not shown in the figure) to improve the alignment uniformity of the alignment film.

In some examples, as shown in FIG. 29, the third non-display region 23 is provided with a fifth common signal transmission line 850, a first gate driving circuit 930, and a first common signal feedback line 940; both the fifth common signal transmission line 850 and the first common signal feedback line 940 are electrically connected to the third common signal transmission line 830, and the first gate driving circuit 930 is electrically connected to a plurality of gate lines 320; and the fifth common signal transmission line 850 and the first common signal feedback line 840 are both located on a side of the first gate driving circuit 930 away from the display region 10, and the first connection line 801 is between the first gate driving circuit 930 and the display region 10.

For example, the gate line 320 may be connected to the first gate driving circuit 930 through the connection line 720 shown in FIG. 22. For example, the first gate driving circuit 930 may include the signal transmission line 710 shown in FIG. 20. For example, the first gate driving circuit 930 may be a GOA gate driving circuit.

For example, a region of the display region away from the circuit board is a far end, and a region of the display region close to the circuit board is a near end. The first common signal feedback line 940 may be used to detect a common signal at the far end. When the first common signal feedback line 940 detects that the waveform of the common signal at the far end has large fluctuation, the common signal at the far end can be compensated through the fifth common signal transmission line 850; and when the first common signal feedback line 940 detects that the common signal at the far end is normal, the fifth common signal transmission line 850 is input with a general common signal. For example, when it is detected that the waveform of the common signal at the far end fluctuates upward relative to the voltage at the common signal balance point, the compensation method adopts reverse complementarity, and when the compensation signal acts on the above-mentioned waveform, the above-mentioned upward fluctuation can be pulled back to the balance point.

In some examples, as shown in FIG. 29, the fourth non-display region 24 is provided with a sixth common signal transmission line 860, a second gate driving circuit 950, and a second common signal feedback line 960; both the sixth common signal transmission line 860 and the second common signal feedback line 960 are electrically connected to the fourth common signal transmission line 840, and the second gate driving circuit 950 is electrically connected to a plurality of gate lines 320; and the sixth common signal transmission line 860 and the second common signal feedback line 960 are both on a side of the second gate driving circuit 950 away from the display region 10, and the second connection line 802 is between the second gate driving circuit 950 and the display region 10.

For example, as shown in FIG. 29, the array substrate adopts a bilateral gate driving technology. For example, the second gate driving circuit 950 may have the same features as the first gate driving structure 930, the second common signal feedback line 960 may have the same features as the first common signal feedback line 940, and the sixth common signal transmission line 860 may have the same features as the fifth common signal transmission line 850, which will not be repeated here.

For example, as shown in FIG. 29, the array substrate further includes a ground line (GND) 972, a test signal line (such as an enhancement signal line, an addition line, ADD) 971, an ESD electrostatic discharge circuit 975, and electrostatic discharge rings (inner short ring) 973 and 974. For example, the common signal transmission line in the array substrate further includes transmission lines 871 and 872, but is not limited thereto, and the transmission lines 871 and 872 may also be omitted.

Another embodiment of the present disclosure provides a display device, including the array substrate as shown in any one of FIG. 29 to FIG. 35.

For example, the display device further includes an opposite substrate. For example, the opposite substrate is provided with a black matrix and a color filter layer. For example, the display device further includes a liquid crystal layer between the array substrate and the opposite substrate.

For example, any of the above-mentioned display devices provided by the embodiments of the present disclosure may be: a mobile phone, a tablet computer, a television, a display, a laptop computer, a digital photo frame, a navigator, a smart watch, a fitness wristband, a personal digital assistant, and any other product or component with a display function. The display device includes, but is not limited to, a radio frequency unit, a network module, an audio output & input unit, a sensor, a user input unit, an interface unit, a memory, a processor, and a power supply. In addition, it may be understood by those skilled in the art that the above-mentioned structures do not constitute a limitation on the above-mentioned display device provided by the embodiments of the present disclosure. In other words, the above-mentioned display device provided by the embodiments of the present disclosure may include more or fewer of the above-mentioned components, or include a combination of certain components, or different component arrangements.

The following statements should be noted:
(1) The drawings of the present disclosure involve only the structures in connection with the embodiments of the present disclosure, and other structure(s) can be referred to common design(s).
(2) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. An array substrate, comprising:
a base substrate, and
a first electrode layer, a plurality of first signal lines, and a plurality of second signal lines on the base substrate,
wherein the plurality of first signal lines are arranged in a first direction, the plurality of second signal lines are arranged in a second direction, and the first direction intersects with the second direction;
the first electrode layer comprises a plurality of first electrodes arranged in an array in the first direction and the second direction, a connection portion is provided between adjacent two first electrodes on two sides of a same first signal line, and the connection portion is configured to connect the two first electrodes; and
the connection portion is closer to the second signal line relative to a straight line that passes through a central region of the first electrode and extends in the first direction.

2. The array substrate according to claim 1, wherein in the second direction, a distance between the first electrode and the second signal line is not greater than a distance between the connection portion and the second signal line.

3. The array substrate according to claim 1, further comprising a plurality of sub-pixels, wherein the plurality of sub-pixels comprise at least a first color sub-pixel and a second color sub-pixel, and both the first color sub-pixel and the second color sub-pixel comprise multiple domains; and a protrusion portion is provided in a light-emitting region of one of the first color sub-pixel and the second color sub-pixel, and the protrusion portion is between two adjacent domains among the multiple domains.

4. The array substrate according to claim 3, wherein in the first color sub-pixel and the second color sub-pixel, the first electrode comprises a plurality of strip electrodes, and extension directions of strip electrodes in two adjacent domains intersect with each other; and
in a direction perpendicular to the base substrate, the protrusion portion overlaps with the strip electrode in at least one of the two adjacent domains, or the protrusion portion does not overlap with the strip electrode.

5. The array substrate according to claim 3, wherein the protrusion portion is provided in a same layer as one of the first signal line and the second signal line.

6. The array substrate according to claim 3, wherein one of the first color sub-pixel and the second color sub-pixel is a red sub-pixel, and the other is a blue sub-pixel.

7. The array substrate according to claim 4, wherein in a direction perpendicular to the base substrate, an edge of the protrusion portion does not overlap with a light-emitting region of an adjacent sub-pixel, and a size of the protrusion portion in an arrangement direction of the two adjacent domains ranges from 1.5 microns to 6 microns;
a width of the connection portion is greater than a width of the strip electrode, and the width of the connection portion is not greater than 10 microns.

8-9. (canceled)

10. The array substrate according to claim 1, wherein a total number of the connection portion provided between the two first electrodes in the first direction is at least one;
the connection portion and the two first electrodes are configured as an integrated structure.

11-12. (canceled)

13. The array substrate according to claim 12, wherein first electrodes of adjacent sub-pixels, which are between two adjacent first signal lines and arranged in the first direction, are configured as an integrated structure; and
a spacing is provided between the first electrodes of adjacent sub-pixels on two sides of the first signal line and arranged in the first direction, and the first signal line is provided in the spacing.

14. The array substrate according to claim 1, comprising a display region and a non-display region on at least one side of the display region,
wherein a plurality of sub-pixels, the plurality of first signal lines, and the plurality of second signal lines are all in the display region; the array substrate further comprises a plurality of signal transmission lines in the non-display region and provided in a same layer as the second signal lines, and comprises connection lines electrically connected to the signal transmission lines; the connection lines extend in the first direction, the signal transmission lines extend in the second direction, and the connection lines are provided in a same layer as the first signal lines; and
in a direction perpendicular to the base substrate, at least one signal transmission line overlaps with the connection lines, and an edge of an overlapping portion of the signal transmission line with the connection lines comprises a notch, so that a size of the overlapping portion in an extension direction of the connection wires is smaller than a size of at least part, except for the overlapping portion, of the signal transmission line in the extension direction of the connection wires.

15. A display device, comprising:
an array substrate according to claim 1;
an opposite substrate provided opposite to the array substrate, wherein the opposite substrate comprises a light-shielding layer, and the light-shielding layer comprises a plurality of openings to define light-emitting regions of sub-pixels;
wherein an orthographic projection of the first signal line on the base substrate comprises a first orthographic projection, an orthographic projection of the connection portion on the base substrate comprises a second orthographic projection, and the second orthographic projection is within an orthographic projection of the light-shielding layer on the base substrate;
an orthographic projection of the opening on the base substrate comprises a third orthographic projection, and a distance between edges, close to each other, of the first orthographic projection and the third orthographic projection is a first distance; and the first orthographic projection comprises an overlapping edge overlapping with the second orthographic projection, a distance between the overlapping edge and a closest edge of the third orthographic projection to the overlapping edge is a second distance, and the second distance is greater than the first distance.

16. The display device according to claim 15, wherein the first signal line extends in the second direction, the opening comprises an opening edge extending in the second direction and closest to the first signal line, and the connection portion is between the opening edge and a second signal line that is closest to the opening edge;
a straight line passing through the connection portion and extending in the first direction does not pass through the opening edge.

17. (canceled)

18. An array substrate, comprising:
a base substrate, comprising a display region and a first non-display region on at least one side of the display region;
a plurality of sub-pixels, in the display region of the base substrate, wherein each of the sub-pixels comprises a first electrode and a second electrode stacked with each other;
a plurality of data lines, in the display region of the base substrate and configured to be electrically connected to second electrodes, wherein the plurality of data lines are arranged in a first direction;
a plurality of gate lines, in the display region of the base substrate and arranged in a second direction, wherein the second direction intersects with the first direction;
a plurality of common electrode lines, in the display region of the base substrate and electrically connected to first electrodes, wherein the plurality of common electrode lines and the plurality of data lines are alternately arranged in the first direction;
wherein the array substrate further comprises a common signal transmission line in the first non-display region, and the common signal transmission line comprises a first common signal transmission line and a second common signal transmission line; the second common signal transmission line is provided on a side of the first common signal transmission line away from the display region, and the common signal transmission line extends in the first direction;
the first common signal transmission line is electrically connected to a part of the plurality of common electrode lines, and the second common signal transmission line is electrically connected to another part of the plurality of common electrode lines; and
the first non-display region further comprises a pad region configured to be electrically connected to a circuit board.

19. The array substrate according to claim 18, further comprising a second non-display region, wherein the first non-display region, the display region, and the second non-display region are arranged sequentially in the second direction; and
the common signal transmission line further comprises a third common signal transmission line and a fourth common signal transmission line both in the second non-display region, the fourth common signal transmission line is on a side of the third common signal transmission line away from the display region, the third common signal transmission line is electrically connected to the second common signal transmission line, and the fourth common signal transmission line is electrically connected to the first common signal transmission line.

20. (canceled)

21. The array substrate according to claim 19, further comprising a transfer portion,
wherein at least one common electrode line is electrically connected to the common signal transmission line through the transfer portion;
the at least one common electrode line comprises a first conductive layer and a second conductive layer stacked with each other, the first conductive layer is provided in a same layer as the data lines, the second conductive layer is provided in a same layer as the first electrode, and at least a portion of the common signal transmission line is provided in a same layer as the gate lines; and
the transfer portion comprises a first transfer layer and a second transfer layer stacked with each other, the first transfer layer is provided in a same layer as the first conductive layer, and the second transfer layer is provided in a same layer as the second conductive layer.

22. The array substrate according to claim 19, further comprising a third non-display region and a fourth non-display region,
wherein the third non-display region, the display region, and the fourth non-display region are arranged sequentially in the first direction; and
the third non-display region is provided with a first connection line to connect the second common signal transmission line and the third common signal transmission line, the fourth non-display region is provided with a second connection line to connect the first common signal transmission line and the fourth common signal transmission line, and at least a portion of the first connection line, at least a portion of the second connection line, and at least a portion of the common signal transmission line are provided in a same layer.

23. The array substrate according to claim 22, wherein the third non-display region is provided with a fifth common signal transmission line, a first gate driving circuit, and a first common signal feedback line;
both the fifth common signal transmission line and the first common signal feedback line are electrically connected to the third common signal transmission line, and the first gate driving circuit is electrically connected to the plurality of gate lines; and
the fifth common signal transmission line and the first common signal feedback line are both on a side of the first gate driving circuit away from the display region, and the first connection line is between the first gate driving circuit and the display region;
the fourth non-display region is provided with a sixth common signal transmission line, a second gate driving circuit, and a second common signal feedback line;
both the sixth common signal transmission line and the second common signal feedback line are electrically connected to the fourth common signal transmission line, and the second gate driving circuit is electrically connected to the plurality of gate lines; and
the sixth common signal transmission line and the second common signal feedback line are both on a side of the second gate driving circuit away from the display region, and the second connection line is between the second gate driving circuit and the display region.

24. (canceled)

25. The array substrate according to claim 18, wherein first electrodes of two columns of sub-pixels between adjacent data lines are electrically connected to a same common electrode line; and
first electrodes of two columns of sub-pixels that are on two sides of a same data line and closest to the same data line are spaced apart from each other, and are electrically connected to the first common signal transmission line and the second common signal transmission line, respectively;
the first common signal transmission line and the second common signal transmission line are configured to transmit different electrical signals.

26. (canceled)

27. A display device, comprising the array substrate according to claim 1.
